(19) United States
(12) Patent Application Publication
(10) Pub. No.: US 2025/0126835 A1
(43) Pub. Date: Apr. 17, 2025

(54) SEMICONDUCTOR DEVICE

(71) Applicant: Samsung Electronics Co., Ltd., Suwon-si (KR)

(72) Inventors: Yongjin LEE, Suwon-si (KR); Min Tae RYU, Suwon-si (KR); Younggeun SONG, Suwon-si (KR); Sanghoon AHN, Suwon-si (KR); Min Hee CHO, Suwon-si (KR); Daewon HA, Suwon-si (KR)

(73) Assignee: Samsung Electronics Co., Ltd., Suwon-si (KR)

(21) Appl. No.: 18/625,457

(22) Filed: Apr. 3, 2024

(30) Foreign Application Priority Data
Oct. 13, 2023 (KR) 10-2023-0136775

(51) Int. Cl. H01L 29/786; H01L 29/66

(52) U.S. Cl. CPC H10D 30/6728; H10D 30/025; H10D 30/6755

(57) ABSTRACT

A semiconductor device may include peripheral circuit structures on a substrate, an interlayer insulating layer on the peripheral circuit structure, a bit line extending in a first direction in the interlayer insulating layer, a semiconductor pattern on the bit line, and including first and second vertical portions facing each other in the first direction and a horizontal portion connecting the first and second vertical portions to each other, first and second word lines on the horizontal portion and adjacent to the first and second vertical portions, respectively, and a gate insulating pattern interposed between the first vertical portion and the first word line, and between the second vertical portion and the second word line. An upper surface of the interlayer insulating layer and an upper surface of the bit line are coplanar with each other.

### CROSS-REFERENCE TO RELATED APPLICATIONS

This U.S. non-provisional patent application claims priority under 35 U.S.C. § 119 to Korean Patent Application No.10-2023-0136775, filed on Oct. 13, 2023, in the Korean Intellectual Property Office, the entire contents of which are hereby incorporated by reference.

### BACKGROUND

Various example embodiments relate to a semiconductor device, and more particularly, relate to a semiconductor device including vertical channel transistors and/or a method of manufacturing the same.

As a design rule of a semiconductor device decrease, a manufacturing technology has been developed to improve integration of the semiconductor device and/or to improve operation speed and/or yield. Accordingly, a transistor with a vertical channel has been proposed to expand the transistor's integration, resistance, and/or current driving ability.

### SUMMARY

Various example embodiments may provide a semiconductor device with improved electrical characteristics and reliability and a method of manufacturing the same.

The problems to be solved or improved upon by example embodiments are not limited to the problems mentioned above, and other problems not mentioned will be clearly understood by those of ordinary skill in the art from the description below.

A semiconductor device according to some example embodiments may include peripheral circuit structures on a substrate, an interlayer insulating layer on the peripheral circuit structure, a bit line in the interlayer insulating layer and extending in a first direction, a semiconductor pattern on the bit line, and including first and second vertical portions facing each other in the first direction and a horizontal portion connecting the first and second vertical portions to each other, first and second word lines, on the horizontal portion and adjacent to the first and second vertical portions, respectively, and a gate insulating pattern interposed between the first vertical portion and the first word line and between the second vertical portion and the second word line. An upper surface of the interlayer insulating layer and an upper surface of the bit line may be coplanar with each other.

Alternatively or additionally a semiconductor device according to some example embodiments may include peripheral circuit structures on a substrate, an interlayer insulating layer on the peripheral circuit structure, a bit line in the interlayer insulating layer and extending in a first direction, a semiconductor pattern on the bit line and including first and second vertical portions facing each other and spaced apart from each other in the first direction, first and second word lines respectively disposed on inner surfaces of the first and second vertical portions, and a gate insulating pattern interposed between the first vertical portion and the first word line, and between the second vertical portion and the second word line. An upper surface of the interlayer insulating layer and an upper surface of the bit line are coplanar with each other.

Alternatively or additionally a method of manufacturing a semiconductor device according to some example embodiments may include forming peripheral circuit structures on a substrate, forming an interlayer insulating layer on the peripheral circuit structure, forming a bit line in the interlayer insulating layer, sequentially stacking a first insulating layer and a sacrificial layer on the interlayer insulating layer and the bit line, patterning the first insulating layer and the sacrificial layer to form a first insulating pattern and a sacrificial pattern crossing the bit line, forming a mold layer covering the first insulating pattern and the sacrificial pattern, patterning the mold layer to form a mold pattern crossing the first insulating pattern and the sacrificial pattern, and performing a surface treatment process on the mold pattern such that a surface of the mold pattern has hydrophobicity.

### BRIEF DESCRIPTION OF THE DRAWINGS

Various example embodiments will be more clearly understood from the following brief description taken in conjunction with the accompanying drawings. The accompanying drawings represent non-limiting, example embodiments as described herein.

FIG. 1 is a block diagram of a semiconductor memory device including a semiconductor device according to some example embodiments.

FIG. 2 is a schematic perspective view of a semiconductor device according to some example embodiments.

FIG. 3 is a plan view of a semiconductor device according to some example embodiments.

FIG. 4 is a cross-sectional view corresponding to line A-A′ in FIG. 3.

FIG. 5A is a cross-sectional view corresponding to line B-B′ in FIG. 3. FIG. 5B is an enlarged view of portion ‘A’ of FIG. 5A.

FIG. 6 is a cross-sectional view corresponding to line C-C′ in FIG. 3.

FIGS. 7A to 7D are cross-sectional views corresponding to line D-D′ in FIG. 3.

FIG. 8 is a cross-sectional view corresponding to E-E′ in FIG. 3.

FIGS. 9A to 15D and FIG. 16 are cross-sectional views showing a method of manufacturing the semiconductor device of FIG. 7A.

FIG. 17 is a cross-sectional view showing a process for manufacturing the semiconductor device of FIGS. 7C and 7D.

### DETAILED DESCRIPTION

Hereinafter, with reference to the drawings, a semiconductor memory device and a manufacturing method thereof according to various example embodiments will be described in detail.

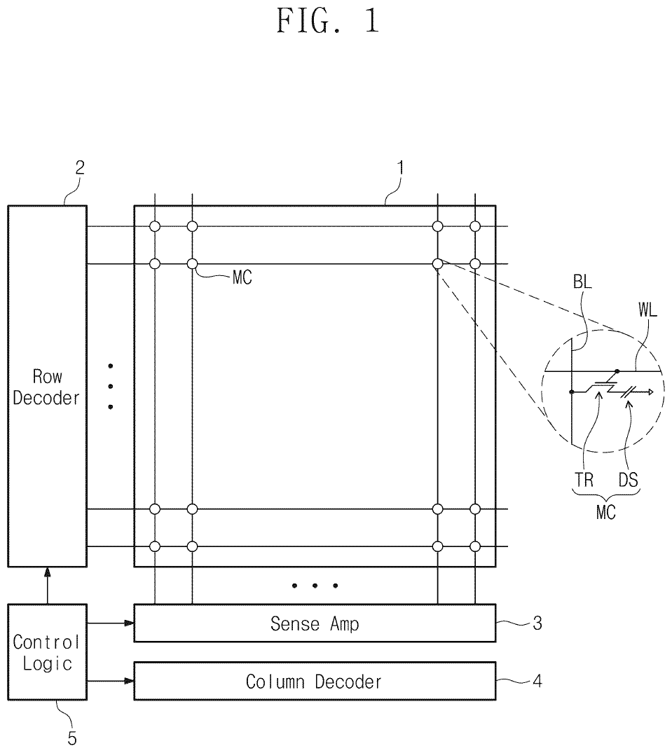

FIG. 1 is a block diagram of a semiconductor memory device including a semiconductor device according to some example embodiments.

Referring to FIG. 1, a semiconductor memory device may include a memory cell array 1, a row decoder 2, a sense amplifier 3, a column decoder 4, and control logic 5.

The memory cell array 1 may include a plurality of memory cells MC, which are two-dimensionally and/or are three-dimensionally arranged. Each of the memory cells MC may be provided between and connected to a word line WL (e.g., a row line) and a bit line BL (e.g., a column line) which cross each other.

Each of the memory cells MC may include a selection element TR and a data storage element DS, which are electrically connected, e.g., in series. The selection element TR may be provided between and connected to the data storage element DS and the word line WL, and the data storage element DS may be connected to the bit line BL through the selection element TR. The selection element TR may be or may include a field effect transistor (FET), and the data storage element DS may be realized using at least one of a capacitor, a memristor, a magnetic tunnel junction pattern, or a variable resistor. As an example, the selection element TR may include a transistor such as an NMOS transistor, a gate electrode of the transistor may be connected to the word line WL, and drain/source terminals of the transistor may be respectively connected to the bit line BL and the data storage element DS. In some example embodiments, at least some of the memory cells MC may be or may include dummy cells, which are not electrically active during operation of the semiconductor device. Alternatively or additionally, at least some of the memory cells MC may be or may include redundancy cells.

The row decoder 2 may be configured to decode address information, which in some example embodiments is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage or a value corresponding to a difference in voltage between one of the bit lines BL, which is selected based on address information decoded by the column decoder 4, and a reference bit line (such as but not limited to a complementary bit line).

The column decoder 4 may provide a data transmission path between the sense amplifier 3 and an external device (e.g., a memory controller). The column decoder 4 may be configured to decode address information, which may be input from the outside, and to select one of the bit lines BL, based on the decoded address information.

The control logic 5 may be configured to generate control signals, which are used to control data writing or reading operations on the memory cell array 1.

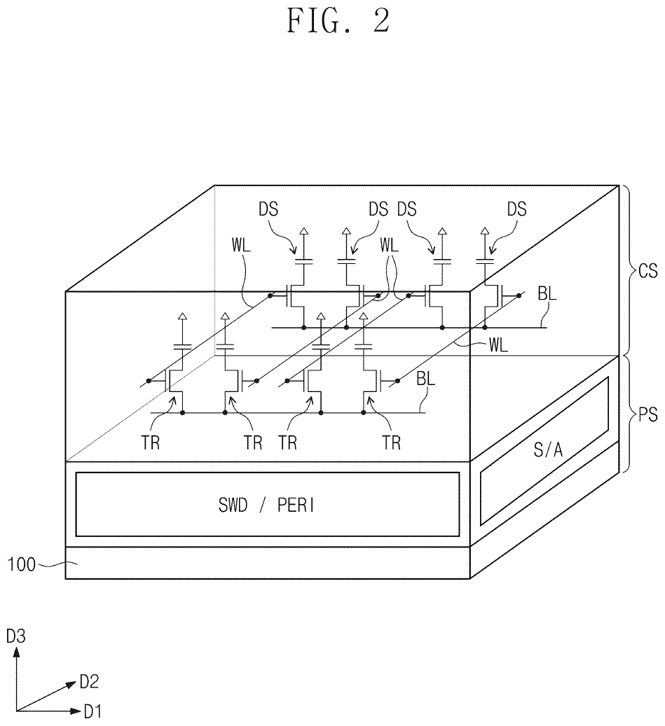

FIG. 2 is a schematic perspective view of a semiconductor device according to some example embodiments.

Referring to FIG. 2, a semiconductor device according to some example embodiments may include a peripheral circuit structure PS on a semiconductor substrate 100 and a cell array structure CS on the peripheral circuit structure PS.

The peripheral circuit structure PS may include core and peripheral circuits, which are formed on the semiconductor substrate 100. The core and peripheral circuits may include the row and column decoders 2 and 4, the sense amplifier 3, and the control logics 5 described with reference to FIG. 1. The peripheral circuit structure PS may be provided between the substrate 100 and the cell array structure CS in a third direction D3 perpendicular to an upper surface of the substrate 100.

The cell array structure CS may include bit lines BL, word lines WL, and memory cells MC (see FIG. 1) therebetween. The memory cells MC (see FIG. 1) may be two-dimensionally and/or three-dimensionally arranged on a plane, which extends in first and second directions D1 and D2 that intersecting each other. Each of the memory cells MC (see FIG. 1) may include the selection element TR and the data storage element DS, as described above.

According to some embodiments, a vertical channel transistor (VCT) may be provided as the selection element TR of each memory cell MC (see FIG. 1). The vertical channel transistor may mean or may correspond to a transistor whose channel region extends in a direction perpendicular to the upper surface of the semiconductor substrate 100 (e.g., in the third direction D3). In some example embodiments, a capacitor and/or a memristor may be provided as the data storage element DS of each memory cell MC (see FIG. 1).

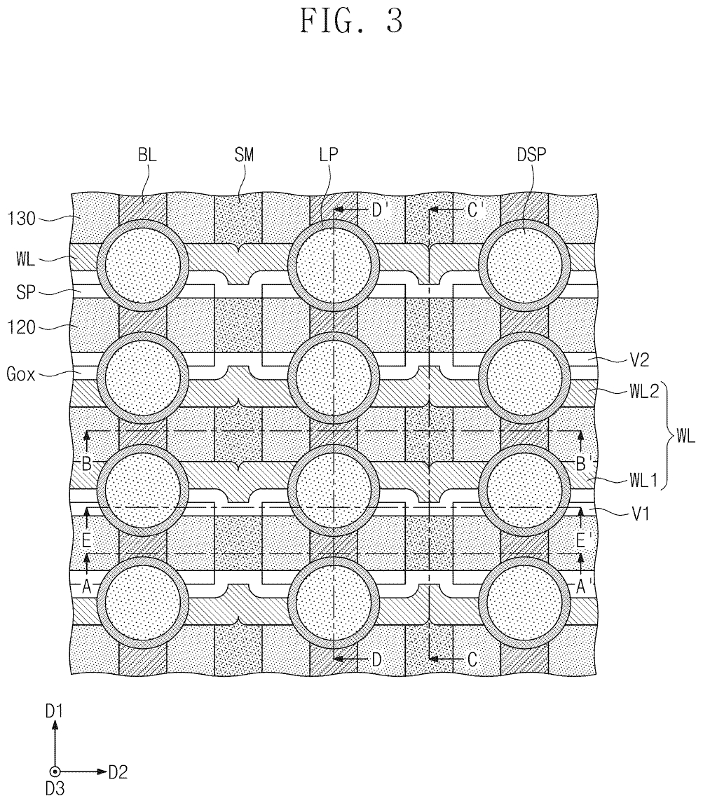

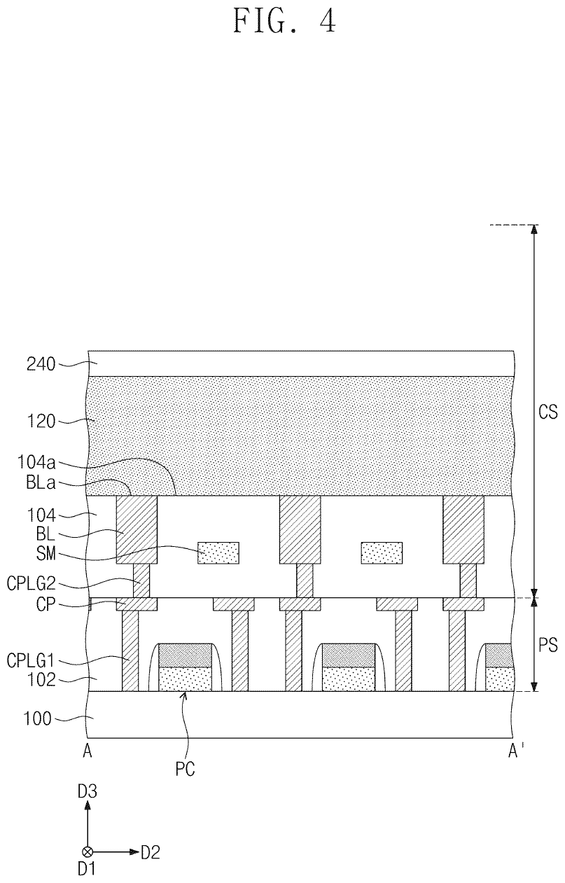

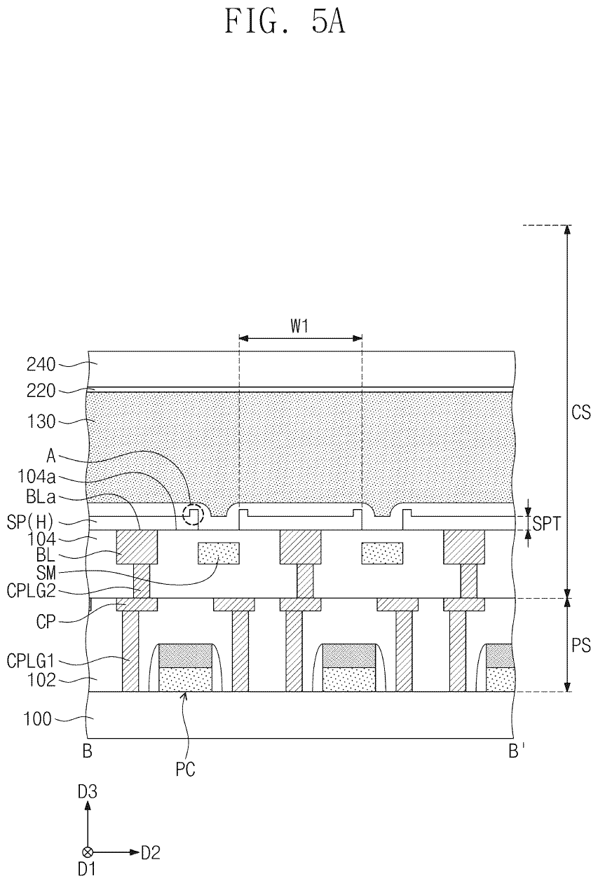

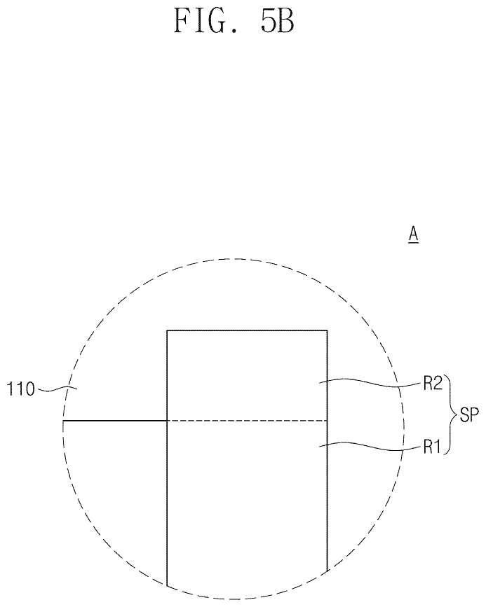

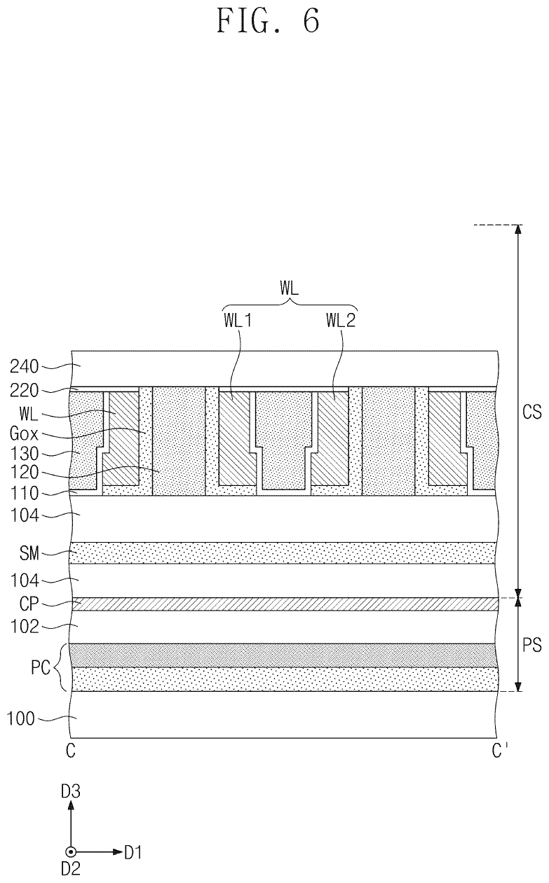

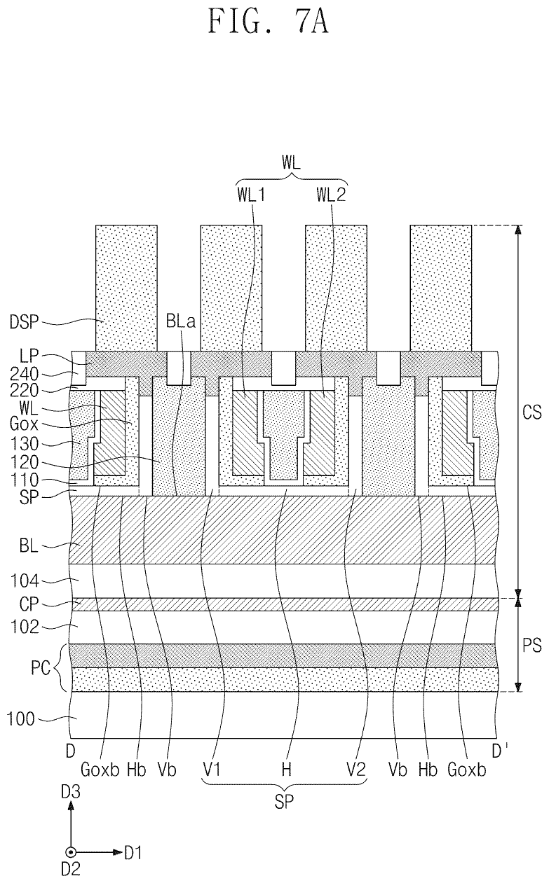

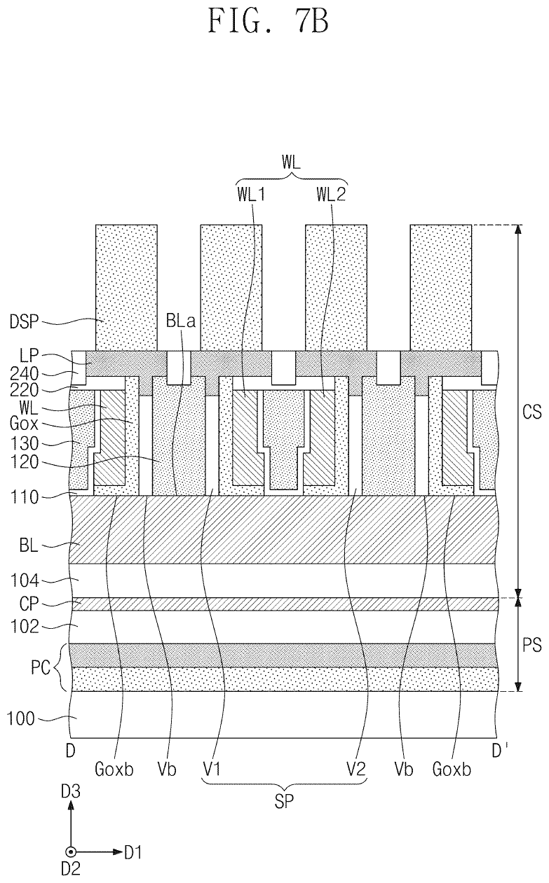

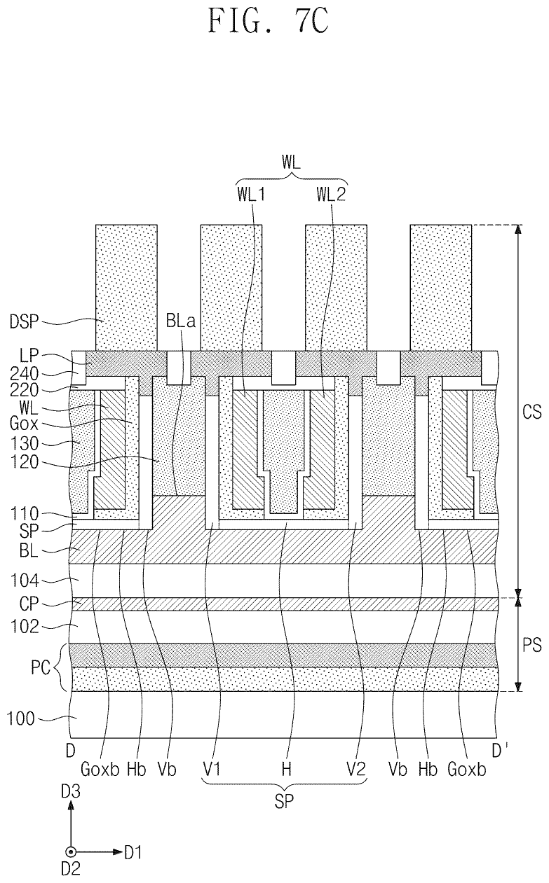

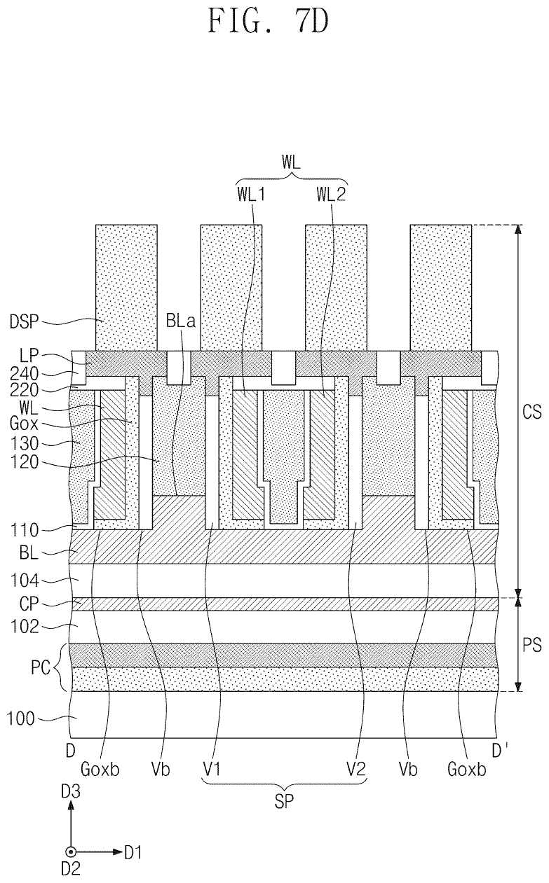

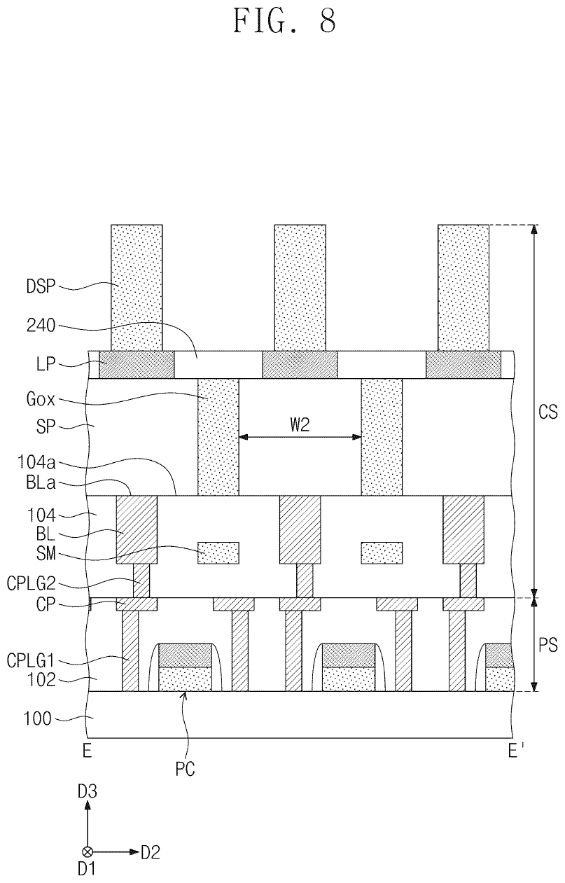

FIG. 3 is a plan view of a semiconductor device according to some example embodiments. FIG. 4 is a cross-sectional view corresponding to line A-A′in FIG. 3. FIG. 5A is a cross-sectional view corresponding to line B-B′ in FIG. 3. FIG. 5B is an enlarged view of portion ‘A’ of FIG. 5A. FIG. 6 is a cross-sectional view corresponding to line C-C′ in FIG. 3. FIGS. 7A to 7D are cross-sectional views corresponding to line D-D′ in FIG. 3. FIG. 8 is a cross-sectional view corresponding to E-E′ in FIG. 3.

Referring to FIGS. 3, 4, 5A, 5B, 6, 7A, and 8, a semiconductor device according to some example embodiments may include a substrate 100, peripheral circuit structure PS on the substrate 100, and a cell array structure CS on the peripheral circuit structure PS.

The substrate 100 may be or may include a semiconductor substrate. The substrate 100 may be or include, for example, one or more of a silicon substrate, a germanium substrate, or a silicon-germanium substrate.

The peripheral circuit structure PS may include a peripheral gate structure PC integrated on the substrate 100, peripheral contact pads CP, peripheral contact plugs CPLG1, and a first interlayer insulating layer 102 covering the peripheral contact plugs CPLG1. The peripheral gate structure PC may include the sense amplifier 3 of FIG. 1.

The cell array structure CS may include memory cells including vertical channel transistors. The cell array structure CS may include a plurality of cell contact plugs CPLG2, a plurality of bit lines BL, a plurality of shielding structures SM, a second interlayer insulating layer 104, a plurality of semiconductor patterns SP, a plurality of word lines WL, a plurality of gate insulating patterns Gox, and data storage patterns DSP. The second interlayer insulating layer 104 may cover the cell contact plugs CPLG2 and the shielding structures SM.

As an example, the peripheral gate structures PC of the peripheral circuit structure PS may be electrically connected to the bit lines BL through the peripheral contact plugs CPLG1, peripheral contact pads CP, and cell contact plugs CPLG2. Each of the first and second interlayer insulating layers 102 and 104 may include multi-layered insulating layers and, for example, may independently or concurrently include at least one of silicon oxide, silicon nitride, silicon oxynitride, and a low dielectric material. Although the peripheral gate structures PC are illustrated as extending in the first direction D1, example embodiments are not limited thereto.

The bit line BL may be provided on the substrate 100 in the second interlayer insulating layer 104 and may extend in the first direction D1. A plurality of bit lines BL may be provided, and the bit lines BL may be spaced apart from each other in the second direction D2. The bit line BL may be electrically connected to the peripheral contact pad CP through the cell contact plug CPLG2.

The bit line BL may include at least one of, for example, doped polysilicon, metal (e.g., one or more of Al, Cu, Ti, Ta, Ru, W, Mo, Pt, Ni, Co), conductive metal nitride (e.g., one or more of TiN, TaN, WN, NbN, TiAIN, TiSiN, TaSiN, RuTiN), conductive metal silicide and/or conductive metal oxide (e.g. one or more of PtO, RuO₂, IrO₂, SrRuO₃ (SRO), (Ba,Sr)RuO₃ (BSRO), CaRuO₃ (CRO), LSCo), but is not limited thereto. The bit line BL may include a single layer or multiple layers of the above-described materials. In some example embodiments, the bit line BL may include a two-dimensional semiconductor material, for example, the two-dimensional material may include graphene, carbon nanotubes, or a combination thereof.

The shielding structures SM may be provided between the bit lines BL, respectively, and the shielding structures SM may extend in the first direction D1. The shielding structures SM may include, for example, a conductive material such as metal. The shielding structures SM may be provided in the second interlayer insulating layer 104, and upper surfaces of the shielding structures SM may be positioned at a lower height than uppermost surfaces BLa of the bit lines BL.

As an example, the shielding structures SM may be formed of a conductive material and may include or define an air gap or void therein. As another example, although not shown, air gaps may be provided in the second interlayer insulating layer 104 instead of or in addition to the shielding structures SM.

The semiconductor pattern SP may be disposed on the bit line BL. A plurality of semiconductor patterns SP may be provided. The semiconductor patterns SP may be spaced apart from each other in the first and second directions D1 and D2.

The semiconductor pattern SP may include a first vertical portion V1, a second vertical portion V2, which face each other, and a horizontal portion H connecting the first and second vertical portions V1 and V2. The horizontal portion H may be adjacent to a lower portion of the first and second vertical portions V1 and V2 to connect the first and second vertical portions V1 and V2.

The horizontal portion H of the semiconductor pattern SP may include a first region R1 and a second region R2, as shown in FIG. 5B. The second region R2 may be disposed on both ends of the first region R1 in the second direction D2. The second region R2 may protrude from the first region R1 in the third direction D3 and may extend in the first direction D1. A thickness SPT of the first region R1 in the third direction D3 of the horizontal portion H of the semiconductor pattern SP may be 1.5 nm to 10 nm; example embodiments are not limited thereto.

The horizontal portion H of the semiconductor pattern SP may have a first width W1 in the second direction D2, as shown in FIG. 5A. As shown in FIG. 8, the first and second vertical portions V1 and V2 of the semiconductor pattern SP may have a second width W2 in the second direction D2. The first width W1 and the second width W2 may be equal to each other.

An upper surface of the bit line BL may extend in a straight line in the first direction D1. A height of the upper surface of the bit line BL may remain substantially the same in the first direction D1. Accordingly, the upper surface of the bit line BL may be the uppermost surface BLa of the bit line BL, which will be described later. The upper surface of the bit line BL may be substantially coplanar with the uppermost surface 104a of the second interlayer insulating layer 104.

The horizontal portion H of the semiconductor pattern SP may be provided on the upper surface of the bit line BL. A lower surface Hb of the horizontal portion H may be in contact with the uppermost surface BLa of the bit line BL and may be positioned at substantially the same height as the uppermost surface BLa of the bit line BL.

The horizontal portion H may include a common source/drain region, and upper portions of the first and second vertical portions V1 and V2 may include first and second source/drain regions, respectively. The first vertical portion V1 may include a first channel region between the common source/drain region and the first source/drain region, and the second vertical portion V2 may include a second channel region between the common source/drain region and the second source/drain region. Each of the first and second vertical portions V1 and V2 may be electrically connected to the bit line BL. That is, the semiconductor device according to the inventive concept may have a structure in which a pair of vertical channel transistors share one bit line BL.

The semiconductor pattern SP may include at least one of an oxide semiconductor, for example, one or more of InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, and InxGayO, but is not limited thereto. In some cases, x+y+z may be equal to one; however, example embodiments are not limited thereto. As an example, the semiconductor pattern SP may include indium gallium zinc oxide (IGZO). The semiconductor pattern SP may include a single layer or multiple layers of an oxide semiconductor. The semiconductor pattern SP may include an amorphous, crystalline, or polycrystalline oxide semiconductor. In some embodiments, the semiconductor pattern SP may have a band gap energy greater than that of silicon. For example, the semiconductor pattern SP may have a bandgap energy of about 1.5 eV to 5.6 eV. For example, the semiconductor pattern SP may have optimal channel performance when the semiconductor pattern SP has a band gap energy of about 2.0 eV to 4.0 eV. For example, the semiconductor pattern SP may be or include a polycrystalline and/or an amorphous phase, but is not limited thereto. In some embodiments, the semiconductor pattern SP may include a two-dimensional semiconductor material, for example, graphene, carbon nanotubes, or a combination thereof. The semiconductor pattern SP may be doped, or may be undoped; example embodiments are not limited thereto.

The word line WL may be disposed between the first vertical portion V1 and the second vertical portion V2. A plurality of word lines WL may be provided. The word lines WL may extend in the second direction D2 and be spaced apart from each other in the first direction D1.

Each of the word lines WL may include a first word line WL1 and a second word line WL2, and the first word line WL1 and the second word line WL2 may face each other in the first direction D1. The first word line WL1 may cover an inner surface of the first vertical portion V1, and the inner surface of the first vertical portion V1 may be one side of the first vertical portion V1 facing the second vertical portion V2.

The first word line WL1 may be adjacent to a first channel region of the first vertical portion V1 and may control the first channel region. The second word line WL2 may cover an inner surface of the second vertical portion V2, and the inner surface of the second vertical portion V2 may be one side of the second vertical portion V2 facing the first vertical portion V1. The second word line WL2 may be adjacent to a second channel region of the second vertical portion V2 and may control the second channel region.

According to some example embodiments, lower portions of the first and second word lines WL1 and WL2 may protrude toward each other. In this case, widths of the lower portions of the first and second word lines W1 and WL2 in the first direction D1 may be greater than widths of upper portions of the first and second word lines W1 and WL2. However, example embodiments are not limited thereto, and for example, although not shown, the widths of the upper and lower portions of the first and second word lines WLI and WL2 may be substantially the same.

The word line WL may include at least one of, for example, doped polysilicon, metal (e.g., one or more of Al, Cu, Ti, Ta, Ru, W, Mo, Pt, Ni, Co), conductive metal nitride (e.g., one or more of TiN, TaN, WN, NbN, TiAIN, TiSiN, TaSiN, RuTiN), conductive metal silicide or conductive metal oxide (e.g. one or more of PtO, RuO₂, IrO2, SrRuO₃ (SRO), (Ba,Sr)RuO₃ (BSRO), CaRuO₃ (CRO), LSCo), but is not limited thereto. The word line WL may include a single layer or multiple layers of the above-described materials. In some example embodiments, the word line WL may include a two-dimensional semiconductor material, for example, graphene, carbon nanotubes, or a combination thereof.

The gate insulating pattern Gox may be interposed between the semiconductor pattern SP and the word line WL. In detail, the gate insulating pattern Gox may be interposed between an inner surface of the first vertical portion V1 and the first word line WL1, and between an inner surface of the second vertical portion V2 and the second word line WL2. The gate insulating pattern Gox may further extend between the horizontal portion H of the semiconductor pattern SP and the word line WL. The word line WL may be separated from the semiconductor pattern SP by the gate insulating pattern Gox. The gate insulating pattern Gox may cover the semiconductor pattern SP with a uniform thickness.

For example, as shown in FIG. 7A, a plurality of gate insulating patterns Gox may be interposed between the first vertical portion V1 and the first word line WL1, and between the second vertical portion V2 and the second vertical portion V2, respectively, and may be separated rather than connected to each other on the horizontal portion H. In some example embodiments, the gate insulation patterns Gox may be spaced apart from each other on the horizontal portion H.

As another example, although not shown, the gate insulation pattern Gox may be interposed between the first vertical portion V1 and the first word line WL1, and between the second vertical portion V2 and the second word line WL2, and may be extended and connected on the horizontal portion H.

The gate insulating pattern Gox may include at least one of silicon oxide, silicon oxynitride, and a high dielectric material having a higher dielectric constant than silicon oxide. The high dielectric materials may include metal oxide and/or metal oxynitride. For example, the high dielectric material capable of being used as the gate insulation pattern Gox may include at least one of HfO₂, HfSiO, HfSiON, HfTaO, HfTiO, HfZrO, ZrO₂, and Al₂O₃, but is not limited thereto.

The first insulating pattern 120 may be interposed between adjacent semiconductor patterns SP in the first direction D1. A plurality of first insulating patterns 120 may be provided. The first insulating patterns 120 may extend in the second direction D2 across the bit line BL and may be spaced apart from each other in the first direction D1. The first insulating pattern 120 may cover at least a portion of outer surfaces of the first and second vertical portions V1 and V2. As an example, the first insulating pattern 120 may include at least one of silicon oxide, silicon nitride, silicon oxynitride, and a low dielectric material. As an example, the first insulating pattern 120 may be formed of a single layer or multiple layers.

For example, as shown in FIG. 7A, the first insulating pattern 120 may be in contact with the uppermost surface BLa of the bit line BL. The first insulating pattern 120 may cover the outer surfaces of the first and second vertical portions V1 and V2 of the semiconductor pattern SP. The lower surface Hb of the horizontal portion H may be positioned at substantially the same height as the lowermost surface of the first insulating pattern 120.

A second insulating pattern 130 may be disposed between the first word line WL1 and the second word line WL2 of the word line WL. A plurality of second insulating patterns 130 may be provided. The second insulating patterns 130 may extend in the second direction D2 across the bit line BL and may be spaced apart from each other in the first direction D1. The first and second insulating patterns 120 and 130 may be alternately arranged in the first direction D1. The second insulating pattern 130 may include, for example, at least one of silicon oxide, silicon nitride, silicon oxynitride, and a low dielectric material.

A protective pattern 110 may be interposed between the word line WL and the second insulating pattern 130. The protective pattern 110 may cover an inner surface of the word line WL and may extend onto the horizontal portion H of the semiconductor pattern SP. As an example, the protective pattern 110 may include at least one of silicon oxide, silicon nitride, and silicon oxynitride.

A capping pattern 220 may be provided on an upper surface of the word line WL.

The capping pattern 220 may cover upper surfaces of the protective pattern 110 and the second insulating pattern 130. The capping pattern 220 may extend in the second direction D2. For example, the capping pattern 220 may include at least one of silicon oxide, silicon nitride, and silicon oxynitride.

Landing pads LP may be disposed on the first and second vertical portions V1 and V2 of the semiconductor pattern SP, respectively. The landing pads LP may be in direct contact with and be electrically connected to the first and second vertical portions V1 and V2. When viewed in a plan view, the landing pads LP may be spaced apart from each other in the first and second directions D1 and D2 and may be arranged in various shapes such as a matrix shape, a zigzag shape, or a honeycomb shape. When viewed in a two-dimensional perspective view, each of the landing pads LP may have various shapes, such as one or more of circular, oval, rectangular, square, diamond, or hexagonal shapes.

The landing pads LP may be formed of or may include, for example, doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, or a combination thereof, but is not limited thereto.

A third interlayer insulating layer 240 may fill a space between the landing pads LP on the first and second insulating patterns 120 and 130. For example, the third interlayer insulating layer 240 may include at least one of silicon oxide, silicon nitride, and silicon oxynitride, and may include a single layer or multiple layers.

Data storage patterns DSP may be respectively disposed on the landing pads LP. The data storage patterns DSP may be electrically connected to the first and second vertical portions V1 and V2 of the semiconductor pattern SP through the landing pads LP, respectively.

According to some example embodiments, the data storage patterns DSP may be or may include a capacitor and may include lower and upper electrodes, and a capacitor dielectric layer interposed therebetween. In this case, the lower electrode may be in contact with the landing pad LP, and the lower electrode may have various shapes, such as circular, oval, rectangular, square, diamond, or hexagon, when viewed in a plan view.

Alternatively or additionally, the data storage patterns DSP may be or may include variable resistance patterns that may be switched between two resistance states by electrical pulses applied to a memory element. For example, the data storage patterns DSP may include one or more of phase-change materials, perovskite compounds, transition metal oxides, and magnetic materials, ferromagnetic materials, or antiferromagnetic materials whose crystal state changes depending on the amount of current.

FIG. 7B is a cross-sectional view corresponding to line D-D′ in FIG. 3, according to various example embodiments. To simplify the explanation, descriptions of content that overlaps with the above-described content are omitted.

Referring to FIG. 7B, a semiconductor pattern SP may include a first vertical portion V1 and a second vertical portion V2 facing each other, and the first and second vertical portions V1 and V2 may be separated. A word line WL may be disposed on each of the first and second vertical portions V1 and V2. The word line WL may include a first word line WL1 on an inner surface of the first vertical portion V1 and a second word line WL2 on an inner surface of the second vertical portion V2. A gate insulating pattern Gox may be interposed between the first vertical portion V1 and the first word line WL1, and between the second vertical portion V2 and the second word line WL2. A second insulating pattern 130 may fill a space between the first word line WL1 and the second word line WL2. Lower surfaces Vb of the first and second vertical portions V1 and V2 may be positioned at substantially the same height as a lower surface Goxb of the gate insulating pattern Gox.

An upper surface of the bit line BL may extend in a straight line in the first direction D1. A height of the upper surface of the bit line BL may remain substantially the same in the first direction D1. Accordingly, the upper surface of the bit line BL may be the uppermost surface BLa of the bit line BL.

The first and second vertical portions V1 and V2 of the semiconductor pattern SP may be provided on the upper surface of the bit line BL. The lower surfaces Vb of the first and second vertical portions V1 and V2 and the lower surface Goxb of the gate insulating pattern Gox may be in contact with the uppermost surface BLa of the bit line BL, and may be positioned at substantially the same height as the uppermost surface BLa of the bit line BL.

For example, as shown in FIG. 7B, the first insulating pattern 120 may be in contact with the uppermost surface BLa of the bit line BL. The first insulating pattern 120 may cover outer surfaces of the first and second vertical portions V1 and V2 of the semiconductor pattern SP. The lower surfaces Vb of the first and second vertical portions V1 and V2 and the lower surface Goxb of the gate insulating pattern Gox may be positioned at substantially the same height as the lowermost surface of the first insulating pattern 120.

FIG. 7C is a cross-sectional view corresponding to line D-D′ in FIG. 3, according to an embodiment of the inventive concept. To simplify the explanation, descriptions of content that overlaps with the above-described content are omitted.

Referring to FIG. 7C, an upper surface of the bit line BL may have a concave-convex structure. The upper surface of the bit line BL below the semiconductor pattern SP may be positioned at a lower height than the uppermost surface BLa of the bit line BL. The uppermost surface BLa of the bit line BL may be or may correspond to an upper surface positioned at the highest height among the upper surfaces of the bit line BL, and may be provided in a region that does not vertically overlap the semiconductor pattern SP.

A lower surface Hb of the horizontal portion H of the semiconductor pattern SP may be positioned at a lower height than the uppermost surface BLa of the bit line BL. For example, the lower surface Hb of the horizontal portion H may be a portion positioned at the lowest height among the lower surfaces of the horizontal portion H, but is not limited thereto. At least a portion of the horizontal portion H may be buried in an upper portion of the bit line BL. For example, as shown in FIG. 7C, an upper surface of the horizontal portion H may be positioned at a lower height than the uppermost surface BLa of the bit line BL, but is not limited thereto. As another example, although not shown, the upper surface of the horizontal portion H may be positioned at a height higher than or at the same level as the uppermost surface BLa of the bit line BL.

Lower portions of the first and second vertical portions V1 and V2 may be buried in the upper portion of the bit line BL. The lower surfaces Vb of the first and second vertical portions V1 and V2 may be substantially coplanar with the lower surface Hb of the horizontal portion H, and may be positioned at a lower height than the uppermost surface BLa of the bit line BL. For example, each of the lower surfaces Vb of the first and second vertical portions V1 and V2 may be a portion positioned at the lowest height among the lower surfaces Vb of the first and second vertical portions V1 and V2, but is not limited thereto. Outer surfaces of lower portions of the first and second vertical portions V1 and V2 may be surrounded by the bit line BL.

The bit line BL having the concave-convex structure, a portion of the word line WL may be buried in the upper portion of the bit line BL. Accordingly, the buried portion of the word line WL may horizontally overlap the bit line BL. Therefore, the word line WL may be effectively controlled or may be more effectively controlled up to a lower portion of each of the first and second channel regions (e.g., to a lower portion of each of the first and second channel regions provided at a height lower than the uppermost surface BLa of the bit line BL), and as a result, electrical characteristics and reliability of the semiconductor device may be improved.

A first insulating pattern 120 may be in contact with the uppermost surface BLa of the bit line BL. The first insulating pattern 120 may cover a portion of the outer surfaces of the first and second vertical portions V1 and V2 that are not buried by the bit line BL. The lower surface Hb of the horizontal portion H of the semiconductor pattern SP may be positioned at a lower height than the lowermost surface of the first insulating pattern 120.

Although not shown, the gate insulating pattern Gox may be interposed between the first vertical portion V1 and the first word line WL1, and between the second vertical portion V2 and the second word line WL2, and may be extended and connected on the horizontal portion H.

FIG. 7D is a cross-sectional view corresponding to line D-D′ in FIG. 3, according to an embodiment of the inventive concept. To simplify the explanation, descriptions of content that overlaps with the above-described content are omitted.

Referring to FIG. 7D, the semiconductor pattern SP may include a first vertical portion V1 and a second vertical portion V2 facing each other, and the first and second vertical portions V1 and V2 may be separated. A word line WL may be disposed on each of the first and second vertical portions V1 and V2. The word line WL may include a first word line WL1 on an inner surface of the first vertical portion V1 and a second word line WL2 on an inner surface of the second vertical portion V2. A gate insulating pattern Gox may be interposed between the first vertical portion V1 and the first word line WL1, and between the second vertical portion V2 and the second word line WL2. A second insulating pattern 130 may fill a space between the first word line WL1 and the second word line WL2. Lower surfaces Vb of the first and second vertical portions V1 and V2 may be positioned at substantially the same height as a lower surface Goxb of the gate insulating pattern Gox. For example, the lower surface Goxb of the gate insulation pattern Gox may be a portion positioned at the lowest height among the lower surfaces of the gate insulation pattern Gox, but is not limited thereto.

An upper surface of the bit line BL may have a concavo-convex structure. The upper surface of the bit line BL may be recessed below a region from an outer surface of the first vertical portion V1 to an outer surface of the second vertical portion V2. The bit line BL may have an uppermost surface BLa below a region between adjacent semiconductor patterns SP in the first direction D1.

Lower portions of the first and second vertical portions V1 and V2 and lower portions of the gate insulating pattern Gox may be buried in an upper portion of the bit line BL. Lower surfaces Vb of the first and second vertical portions V1 and V2 and the lower surface Goxb of the gate insulating pattern Gox may be positioned at a lower height than the uppermost surface BLa of the bit line BL. The lower portions of the first and second vertical portions V1 and V2 may be in contact with the bit line BL. As an example, a portion of the word line WL may be buried in the upper portion of the bit line BL. The buried portion of the word line WL may horizontally overlap the bit line BL. Lower surfaces of the first and second word lines WL1 and WL2 may be positioned at a lower height than the uppermost surface BLa of the bit line BL.

A first insulating pattern 120 may be in contact with the uppermost surface BLa of the bit line BL. The first insulating pattern 120 may cover the outer surfaces of the first and second vertical portions V1 and V2 of the semiconductor pattern SP. The lower surfaces Vb of the first and second vertical portions V1 and V2 and the lower surface Goxb of the gate insulating pattern Gox may be positioned at a lower height than the lowermost surface of the first insulating pattern 120.

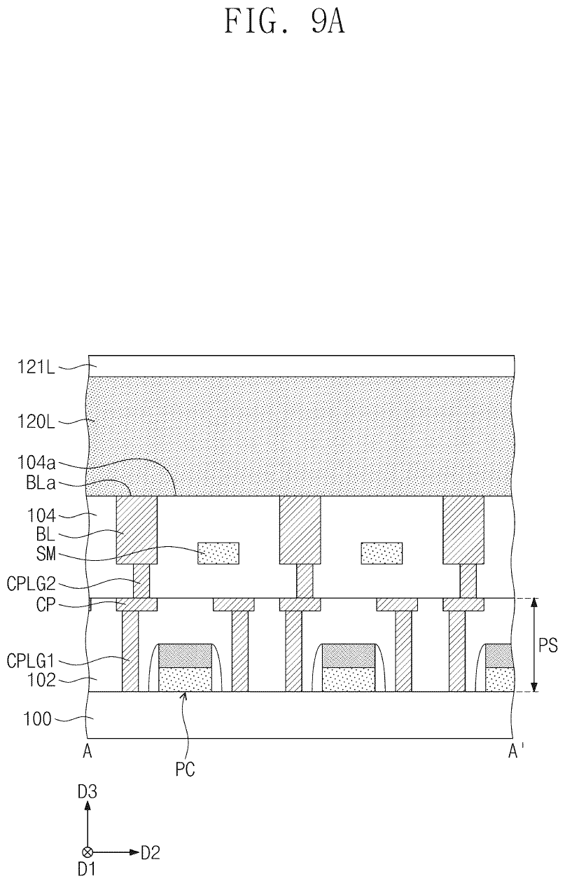

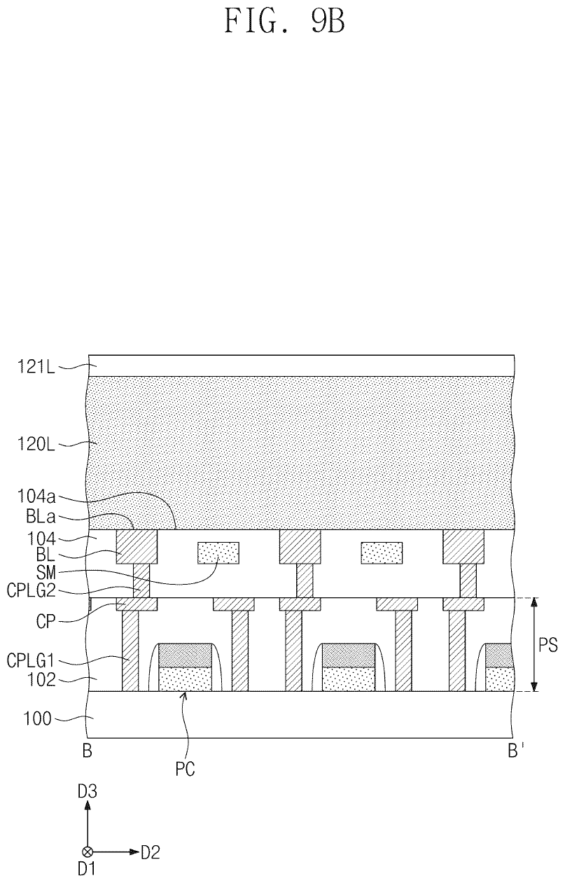

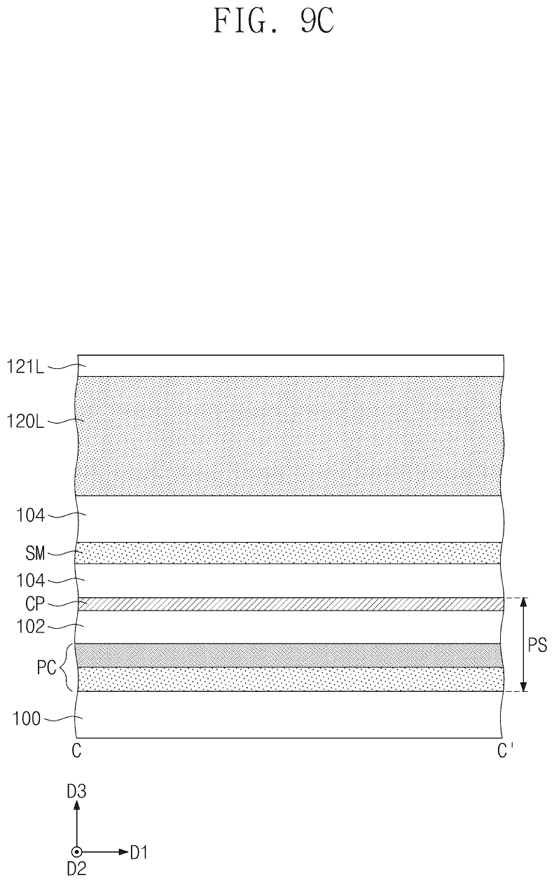

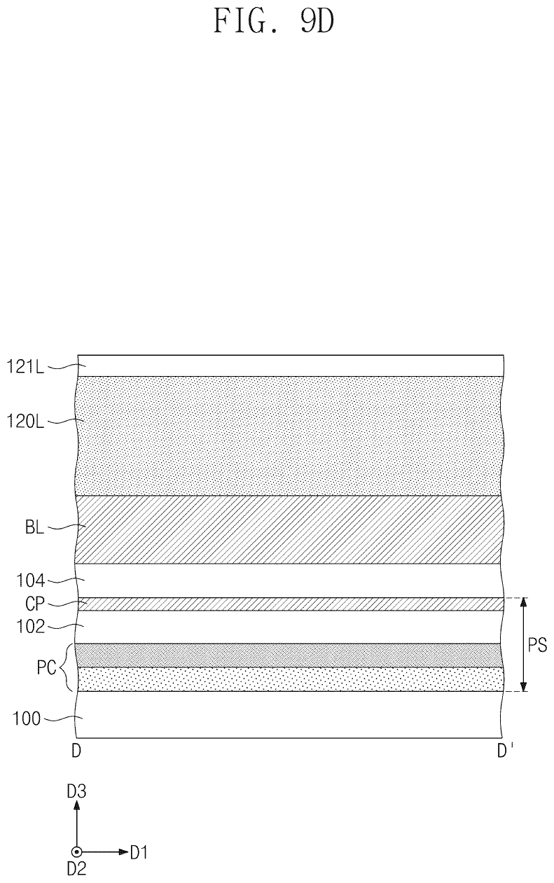

FIGS. 9A to 15D and FIG. 16 are cross-sectional views showing a method of manufacturing the semiconductor device of FIG. 7A. Hereafter, the method of manufacturing the semiconductor device of FIG. 7A will be described with reference to FIGS. 3, 9A to 15D, and 16. To simplify the explanation, descriptions of content that overlaps with the above-described content are omitted.

Referring to FIG. 3 and FIGS. 9A to 9D, a peripheral circuit structure PS may be formed on a substrate 100. Forming the peripheral circuit structure PS may include forming a peripheral gate structure PC, peripheral contact pads CP, peripheral contact plugs CPLG1, and a first interlayer insulating layer 102 covering them. A second interlayer insulating layer 104 may be formed on the peripheral circuit structure PS. A bit line BL may be formed in the second interlayer insulating layer 104. A plurality of bit lines BL may be provided. The bit lines BL may extend in a first direction D1 and be spaced apart from each other in a second direction D2. The bit line BL may be formed to be electrically connected to lower wirings and wirings in the peripheral circuit structure PS. Forming the bit line BL may include depositing a bit line layer (not shown) and patterning the bit line layer to form the bit line BL. The process of forming the peripheral circuit PS may include one or more of a deposition process such as but not limited to a chemical vapor deposition process, an etching process such as but not limited to a wet etching and/or a dry etching process, a chemical mechanical planarization process, a photolithography process, an ion implantation process, and a thermal process; example embodiments are not limited thereto.

A first insulating layer 120L and a sacrificial layer 121L may be sequentially formed on the second interlayer insulating layer 104 and the bit line BL. In some cases, the first insulating layer 120L and the sacrificial layer 121L may be formed in an in-situ process; example embodiments are not limited thereto. The first insulating layer 120L and the sacrificial layer 121L may entirely cover the second interlayer insulating layer 104 and the bit line BL. The first insulating layer 120L may include, for example, at least one of silicon oxide, silicon nitride, silicon oxynitride, and a low dielectric material. The sacrificial layer 121L may include, for example, silicon nitride.

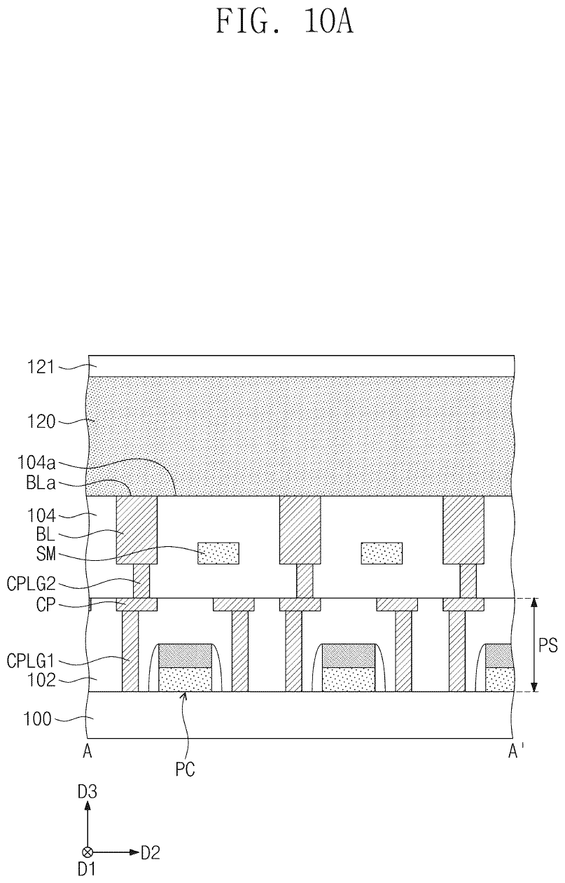

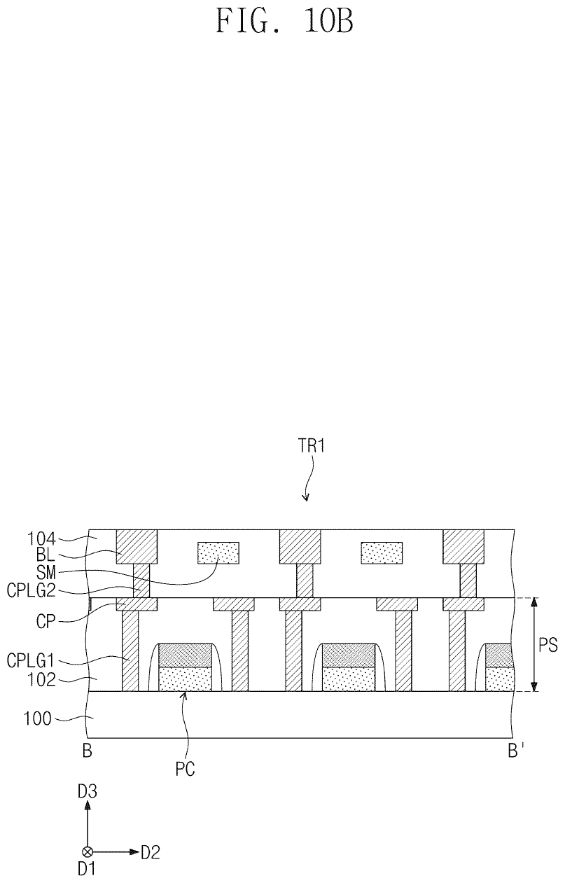

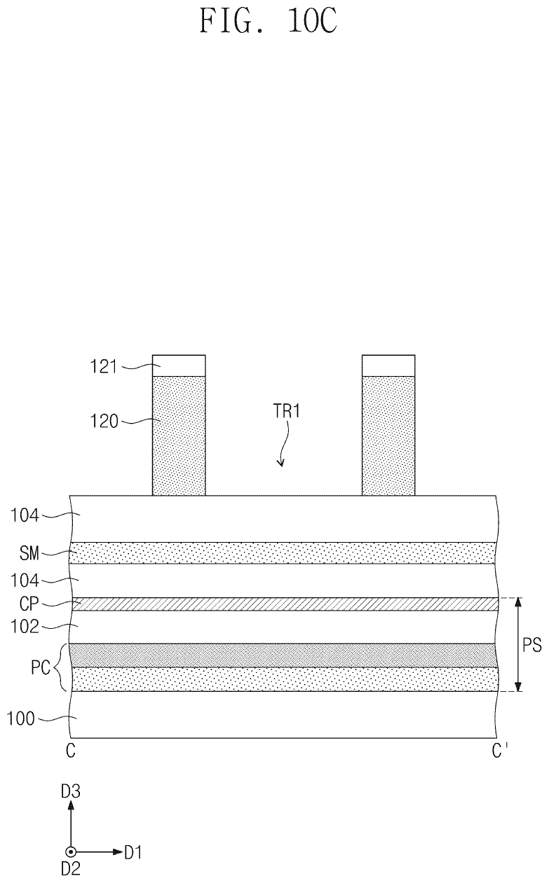

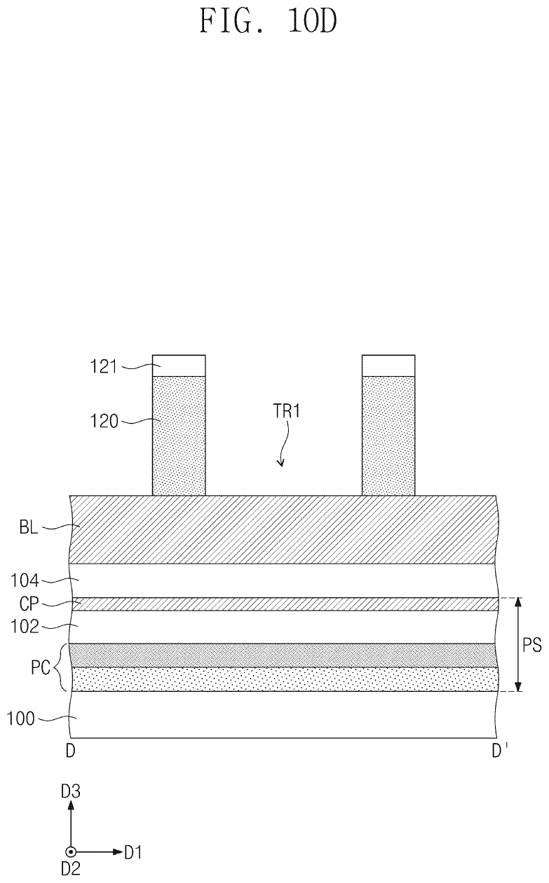

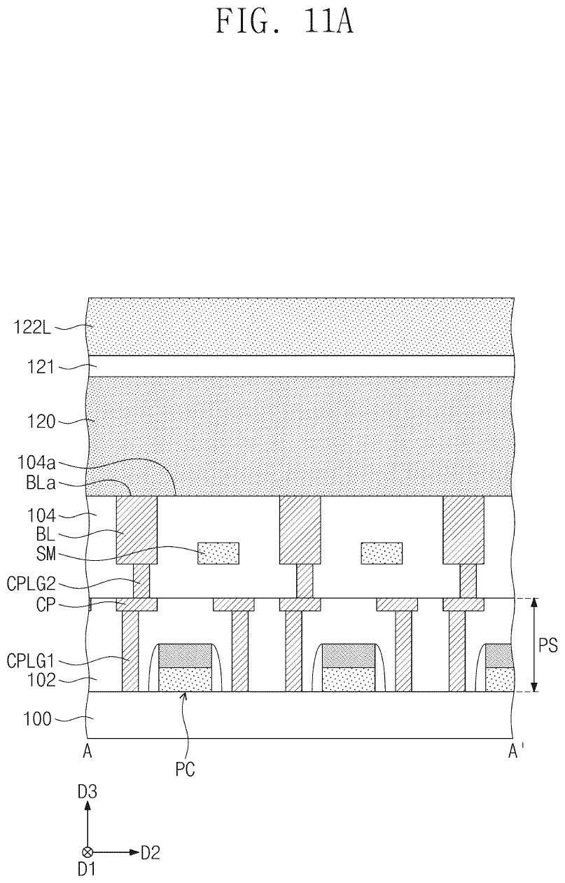

Referring to FIG. 3 and FIGS. 10A to 10D, a first insulating pattern 120 and a sacrificial pattern 121 may be formed. Forming the first insulating pattern 120 and the sacrificial pattern 121 may include forming a mask pattern (not shown) on the sacrificial layer 121L, sequentially etching the sacrificial layer 121L and the first insulating layer 120L using the mask pattern as an etch mask, and removing the mask pattern. In the etching process, the bit line BL may not be etched. The etching process may include a wet etching process and/or a dry etching process. The first insulating pattern 120 and the sacrificial pattern 121 may be formed in the plural. The first insulating patterns 120 and sacrificial patterns 121 may extend in the second direction D2 and be spaced apart from each other in the first direction D1.

The first insulating pattern 120 and the sacrificial pattern 121 may have a first trench region TR1. The first trench region TR1 may be provided in the plural, and may extend in the second direction D2. The first trench region TR1 may expose side surfaces of the first insulating pattern 120, upper and side surfaces of the sacrificial pattern 121, a portion of the second interlayer insulating layer 104, and a portion of the bit line BL.

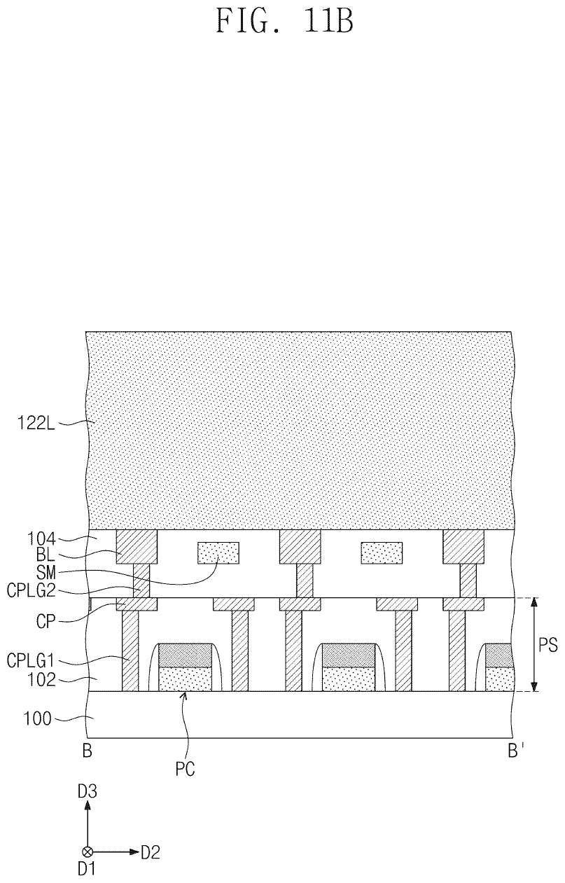

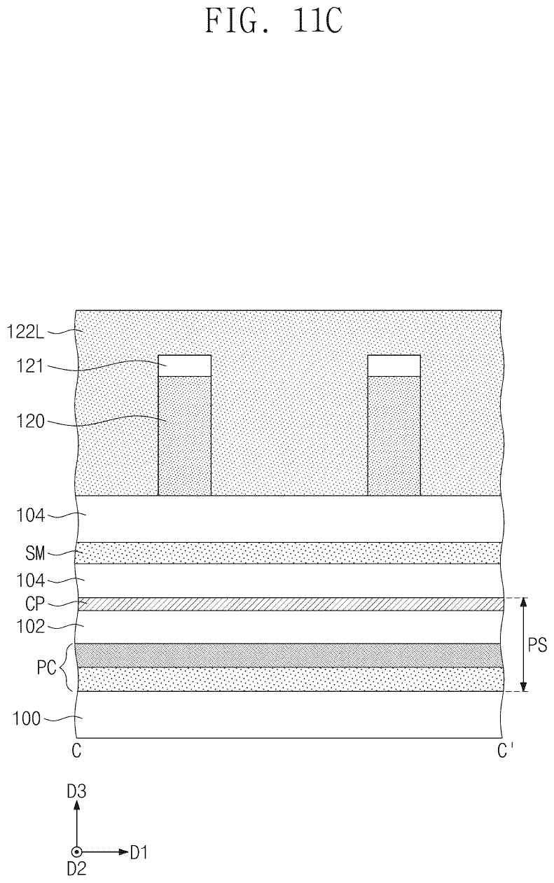

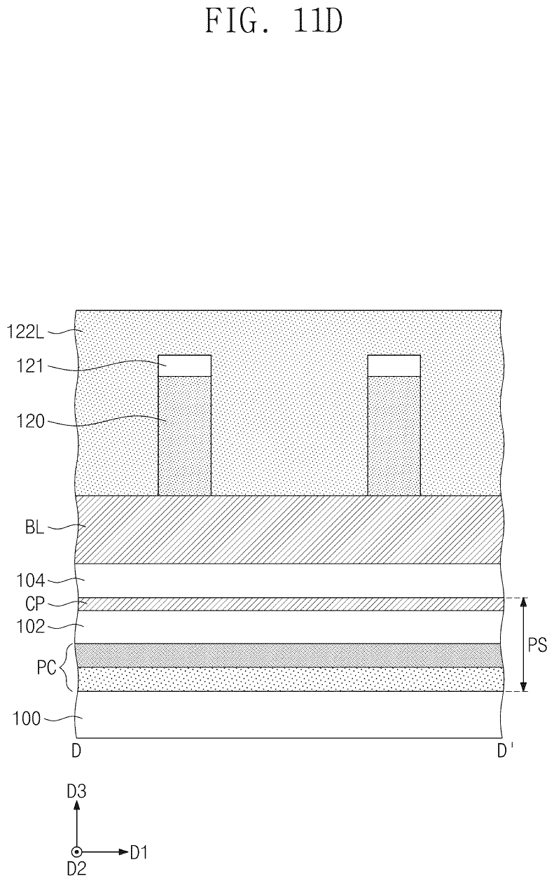

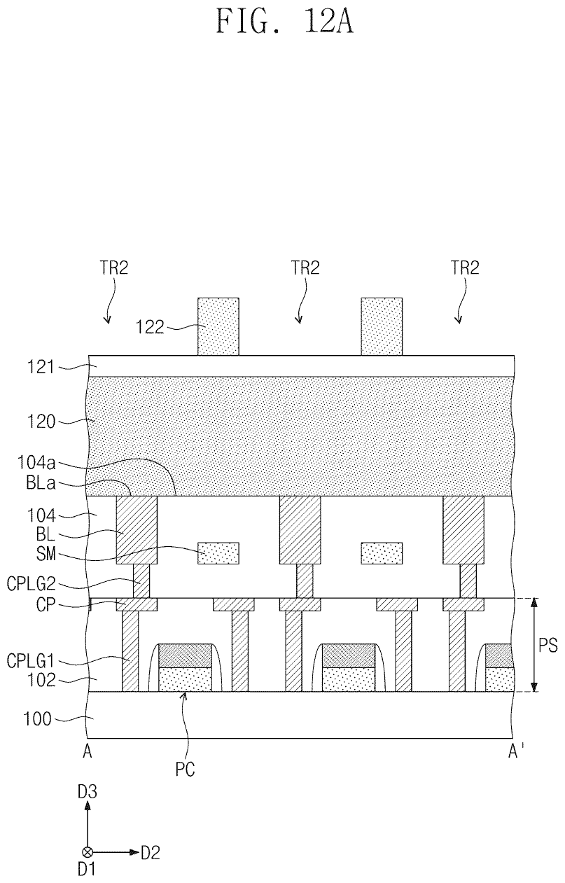

Referring to FIG. 3 and FIGS. 11A to 11D, a mold layer 122L may be formed covering the first insulating pattern 120 and the sacrificial pattern 121. Forming the mold layer 122L may be formed using a layer-forming technology such as one or more of chemical vapor deposition (CVD), physical vapor deposition (PVD), etc. The mold layer 122L may also cover the second interlayer insulating layer 104 and the bit line BL. The mold layer 122L may entirely cover the first insulating pattern 120, the sacrificial pattern 121, the second interlayer insulating layer 104, and the bit line BL.

The mold layer 122L may include a material containing carbon. For example, the mold layer 122L may include a spin-on hardmask (SOH) and/or an amorphous carbon layer (ACL).

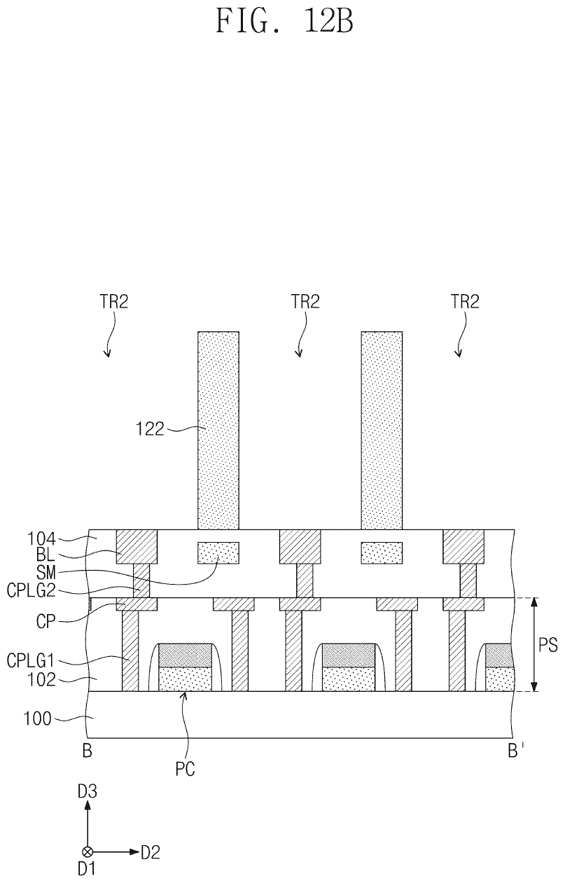

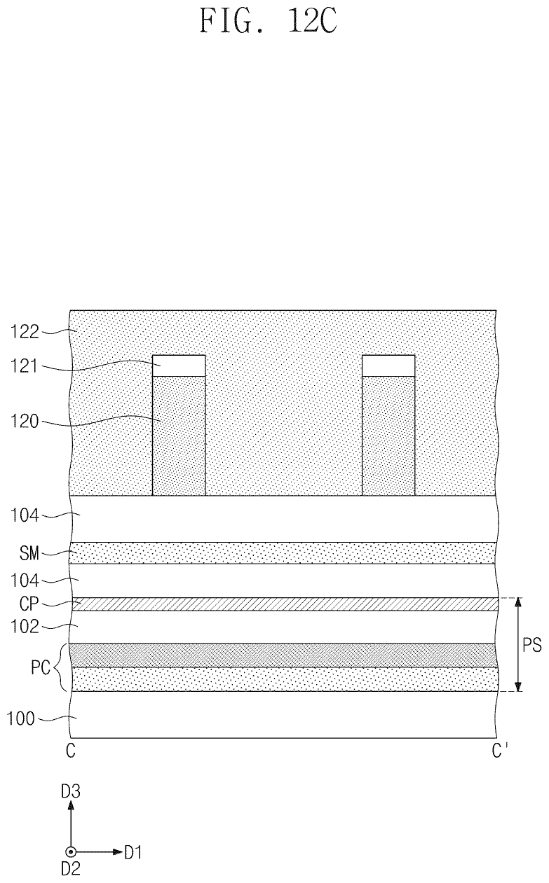

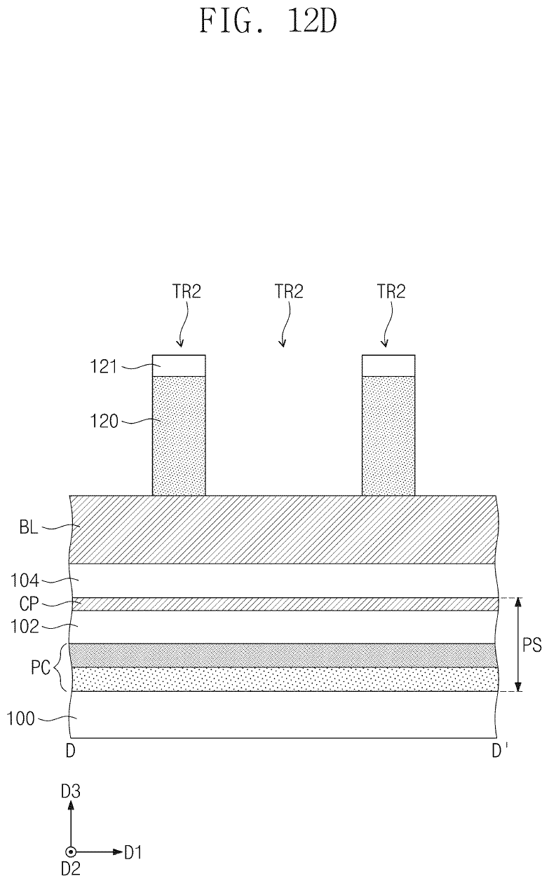

Referring to FIG. 3 and FIGS. 12A to 12D, a mold pattern 122 may be formed. Forming the mold pattern 122 may include forming a mask pattern (not shown) on the mold layer 122L, etching the mold layer 122L using the mask pattern as an etch mask, and removing the mask pattern. In the etching process, the bit line BL, the second interlayer insulating layer 104, the first insulating pattern 120, and the sacrificial pattern 121 may not be etched. The mold pattern 122 may be formed in the plural. The mold patterns 122 may extend in the first direction D1 and be spaced apart from each other in the second direction D2. When viewed in a plan view, the mold pattern 122 may not be formed in a portion that vertically overlaps the bit line BL.

The mold pattern 122 may have a second trench region TR2. The second trench region TR2 may be provided in the plural, and may extend in the first direction D1. When viewed a plan view, the second trench region TR2 may be formed in a portion that vertically overlaps the bit line BL. A portion of the second interlayer insulating layer 104, a portion of the bit line BL, side surfaces of the first insulating pattern 120, and upper and side surfaces of the sacrificial pattern 121 may be exposed by the second trench region TR2.

After the mold pattern 122 is formed, a surface treatment process (H2 treatment) may be performed by providing hydrogen plasma. Hydrophobic C—H bonds may be formed on a surface of the mold pattern 122 through the surface treatment process.

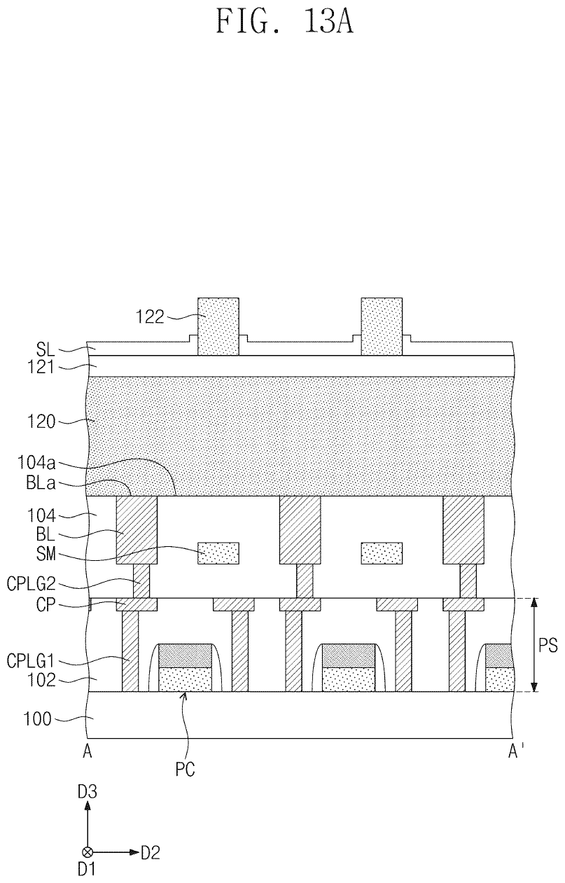

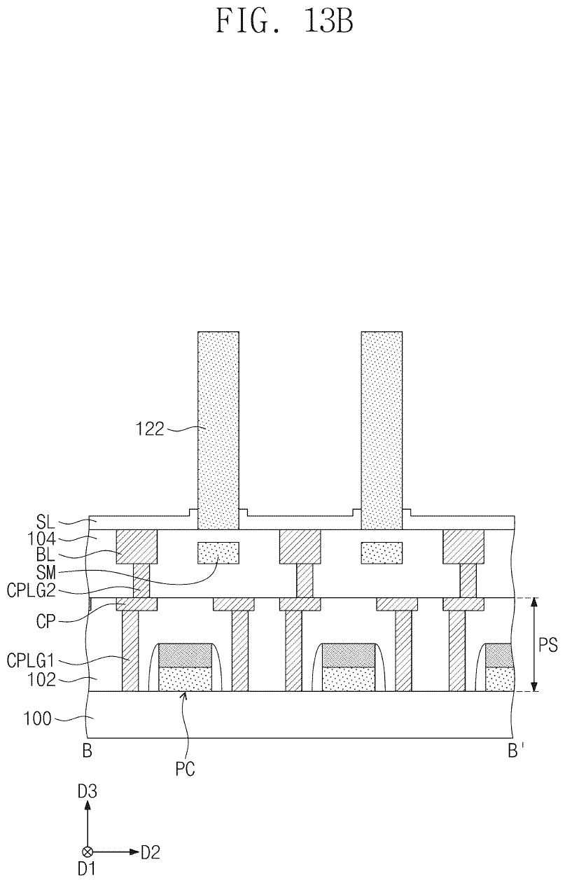

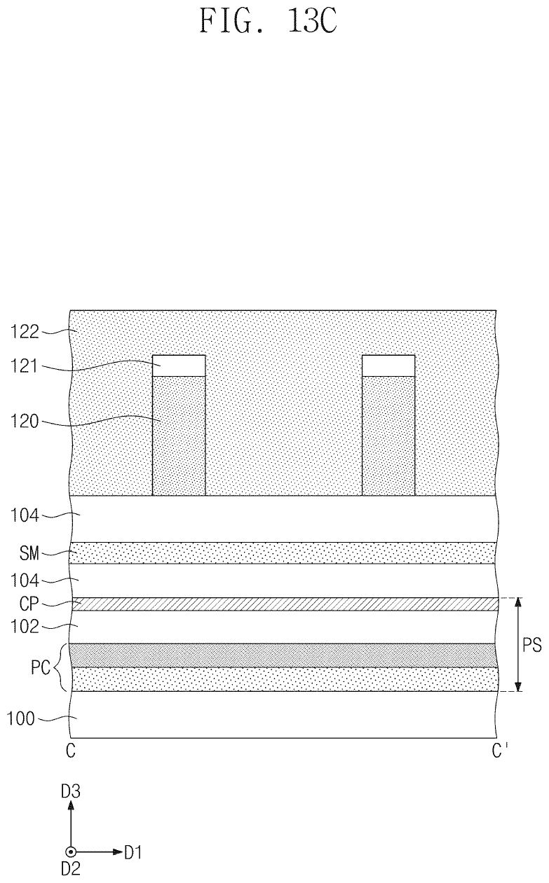

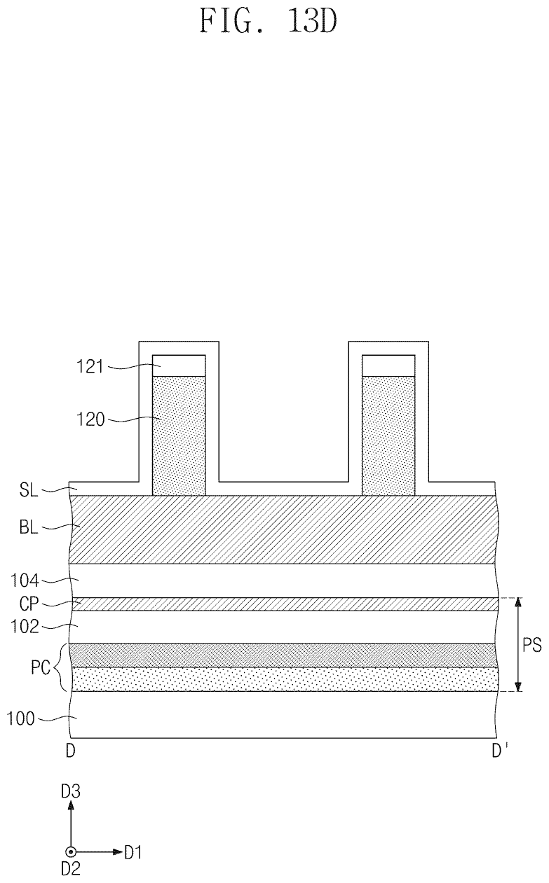

Referring to FIG. 3 and FIGS. 13A to 13D, a semiconductor layer SL may be formed. The semiconductor layer SL may be formed using a layer-forming technology with excellent step coating characteristics, such as one or more of chemical vapor deposition (CVD), physical vapor deposition (PVD), and atomic layer deposition (ALD). The semiconductor layer SL may fill a portion of the second trench region TR2. In detail, the semiconductor layer SL may conformally cover a portion of the second interlayer insulating layer 104 exposed by the second trench region TR2, a portion of the bit line BL, and side surfaces of the first insulating pattern 120, and the upper and side surfaces of the sacrificial pattern 121. Accordingly, as described above with reference to FIGS. 5A and 8, a width of the semiconductor pattern SP in the second direction D2 may be formed to be the same.

During the process of forming the semiconductor layer SL, the semiconductor layer SL may not be formed on the mold pattern 122. Forming the semiconductor layer SL in the mold pattern 122 is suppressed by the surface treatment process using the hydrogen plasma. However, as shown in FIGS. 13A and 13B, a portion of the semiconductor layer SL may be formed in a lower portion adjacent to a lower surface of the mold pattern 122. For example, the semiconductor layer SL may include a portion protruding in the third direction D3 from a portion adjacent to the mold pattern 122. Accordingly, as described above with reference to FIGS. 5A and 5B, a horizontal portion H of the semiconductor pattern SP may include a first region R1 and a second region R2, and the second region R2 may be disposed on both ends of the first region R1 in the second direction D2. The second region R2 may protrude in the third direction D3 and may extend in the first direction D1.

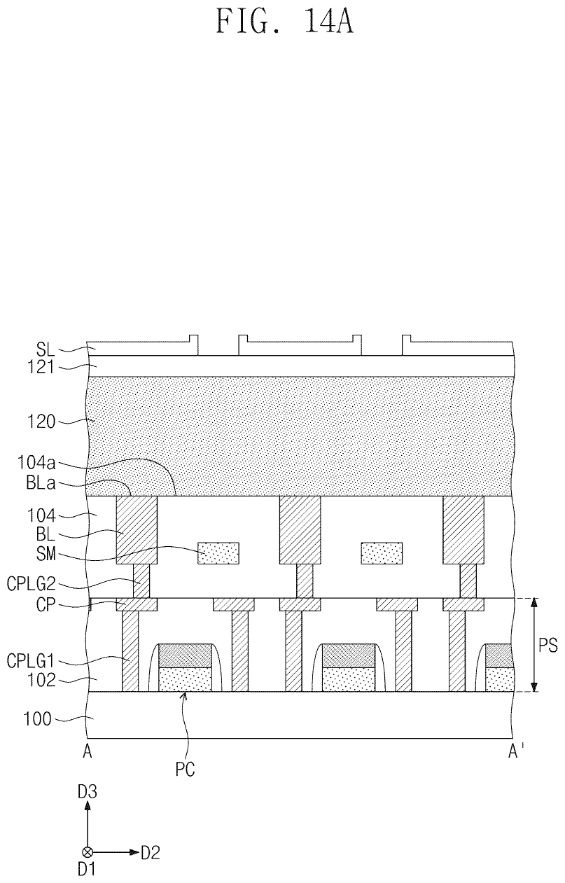

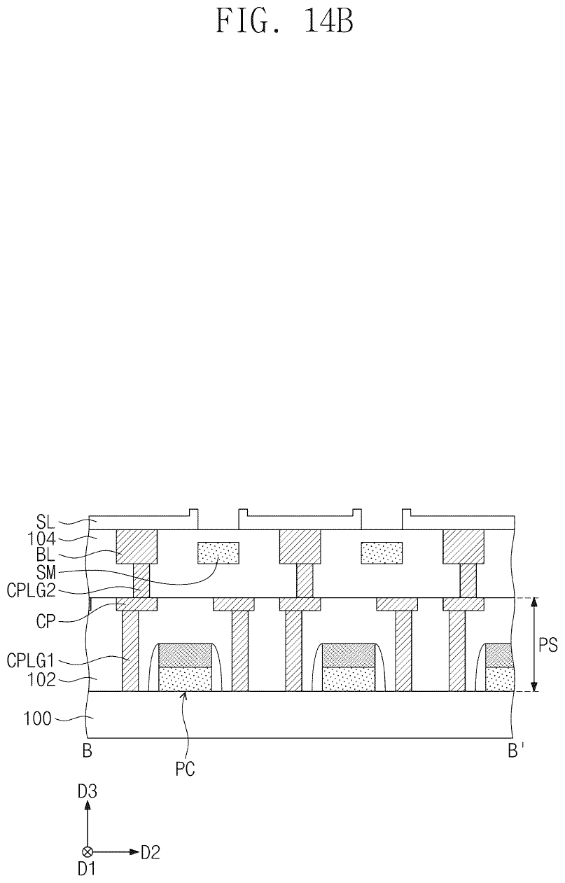

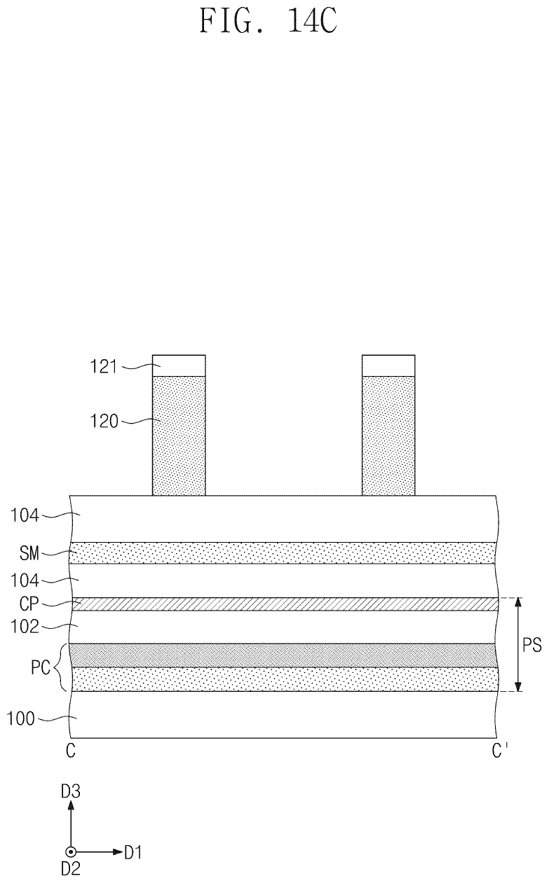

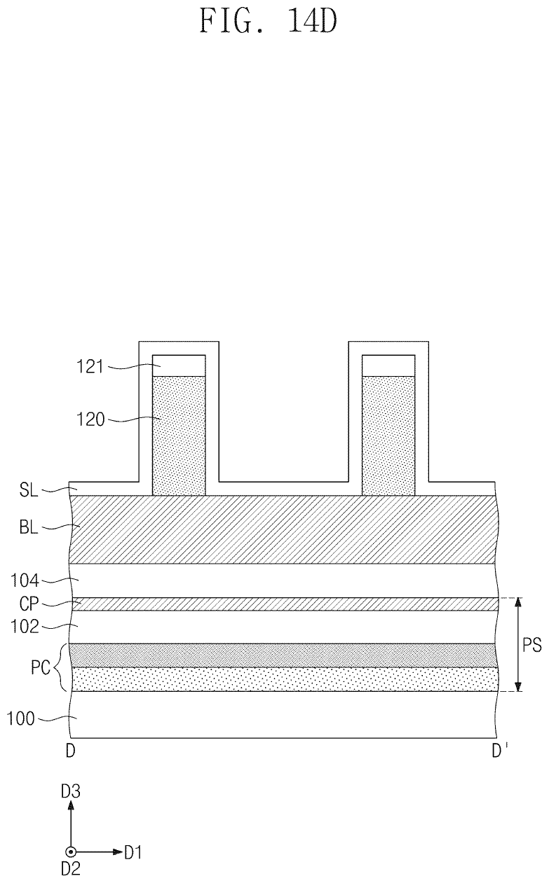

Referring to FIG. 3 and FIGS. 14A to 14D, the mold pattern 122 may be removed. Removing the mold pattern 122 may be performed through a wet etching process.

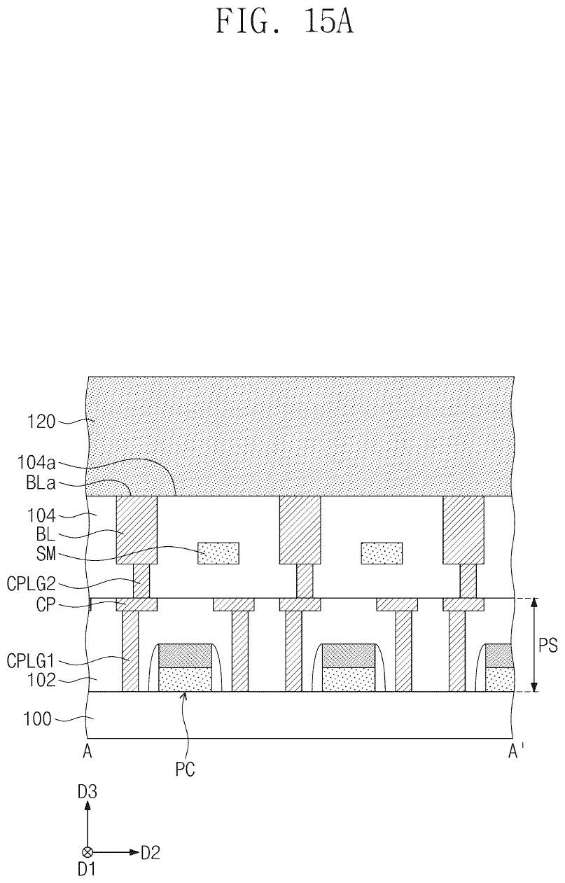

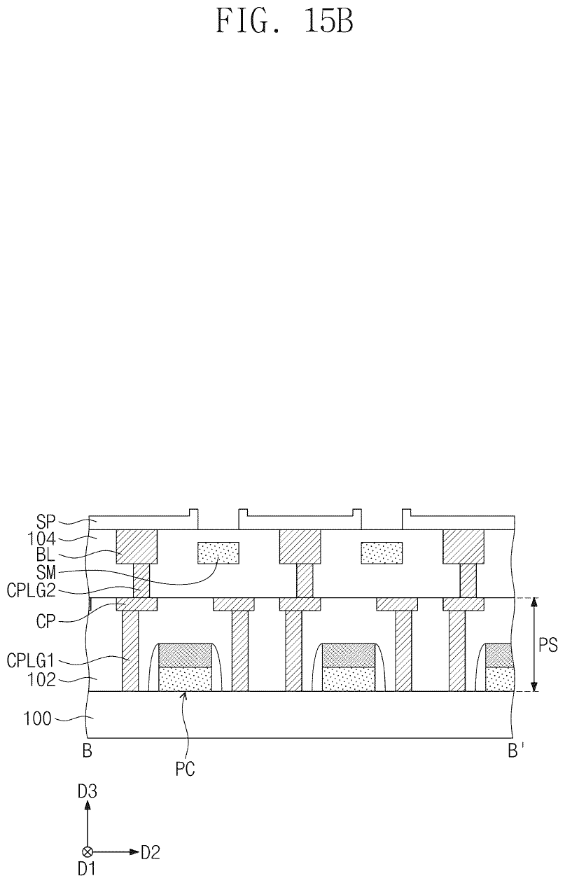

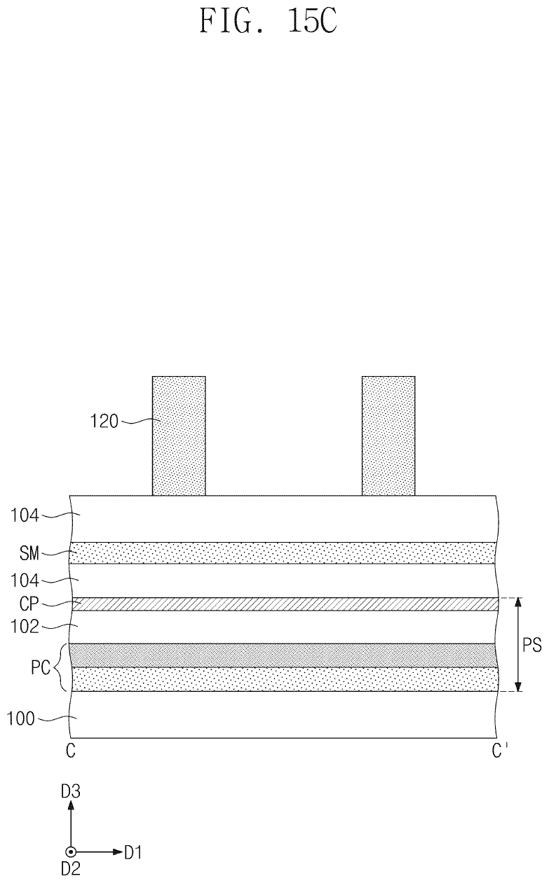

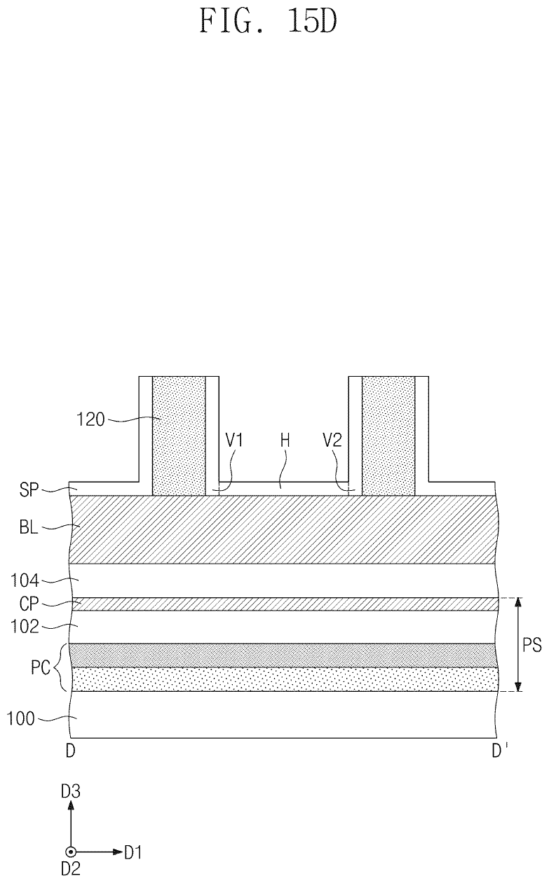

Referring to FIG. 3 and FIGS. 15A to 15D, a portion of the semiconductor layer SL and the sacrificial pattern 121 may be removed. Removing a portion of the semiconductor layer SL may include removing the semiconductor layer SL on regions provided between the bit lines BL adjacent to each other in the second direction D2 and extending in the first direction D1. The semiconductor layer SL may be separated into a plurality of semiconductor patterns SP through the removing of the semiconductor layer SL. Each of the semiconductor patterns SP may include a first vertical portion V1, a second vertical portion V2 facing each other, and a horizontal portion H connecting the first and second vertical portions V1 and V2.

Although not shown, in the process of removing the semiconductor layer SL, the horizontal portion H of the semiconductor pattern SP may also be removed. Accordingly, as shown in FIG. 7B, the semiconductor pattern SP may include first and second vertical portions V1 and V2, and the first and second vertical portions V1 and V2 may be spaced apart from each other.

Referring to FIGS. 3 and 16, a gate insulating layer GIL, a conductive layer CL, and a protective layer 112 may be formed to entirely cover upper surfaces of the first insulating pattern 120, the semiconductor pattern SP, and the second interlayer insulating layer 104. The gate insulating layer GIL, the conductive layer CL, and the protective layer 112 may conformally cover inner surfaces of the first and second vertical portions V1 and V2, an upper surface of the horizontal portion H, and an upper surface of the first insulating pattern 120. Forming the gate insulating layer GIL, conductive layer CL, and protective layer 112 may be formed using a layer-forming technology with excellent step coating characteristics such as one or more of chemical vapor deposition (CVD), physical vapor deposition (PVD), and atomic layer deposition (ALD).

Referring again to FIGS. 3 and 7A, a word line WL and a gate insulating pattern Gox may be formed. The word line WL may be formed to include a first word line WL1 on the first vertical portion V1 and a second word line WL2 on the second vertical portion V2. Forming the word line WL may include, for example, removing the conductive layer CL on the first insulating pattern 120 and the horizontal portion H to separate the conductive layer CL into a plurality of word lines WL.

When forming the word line WL, the gate insulating layer GIL on the first insulating pattern 120 and the horizontal portion H may be removed and separated into a plurality of gate insulating patterns Gox. As another example, although not shown, when forming the word line WL, the gate insulating layer GIL on the first insulating pattern 120 may be removed to be separated into a plurality of gate insulating patterns Gox, and the gate insulating layer GIL on the horizontal portion H may remain without being removed to form a portion of the gate insulating pattern Gox. In this case, the gate insulating pattern GIL may have a U-shape connected on the horizontal portion H.

As an example, although not shown, when forming the word line WL and the gate insulating pattern Gox, a portion of the horizontal portion H of the semiconductor pattern SP may be further removed. In this case, the horizontal portion H may be divided into first and second sub-horizontal portions (not shown) connected to the first and second vertical portions V1 and V2, respectively, and the first and second sub-horizontal portions may be separated apart from each other. The first vertical portion V1 and the first sub-horizontal portion may be connected to each other to have an ‘L’-shape, and the second vertical portion V2 and the second sub-horizontal portion may be connected to each other to have an ‘L’-shape.

As an example, an upper surface of the word line WL may be formed to be positioned at a lower height than an upper surface of the gate insulating pattern Gox and an upper surface of the first insulating pattern 120.

A portion of the protective layer 112 may be removed in the removal process. After the removal process, an additional protective layer (not shown) may be formed on the remainder of the protective layer 112, and the remainder of the protective layer 112 and the additional protective layer may form the protective pattern 110.

Thereafter, a second insulating pattern 130 may be formed between the first word line WL1 and the second word line WL2. Forming the second insulating pattern 130 may include forming a second insulating layer (not shown) covering the semiconductor pattern SP, gate insulating pattern Gox, and word line WL, and removing an upper portion of the second insulating layer to separate the second insulating layer into a plurality of second insulating patterns 130. An upper surface of the second insulating pattern 130 may be positioned at a lower height than the upper surface of the gate insulating pattern Gox and the upper surface of the first insulating pattern 120, and may be formed at a height adjacent to the upper surface of the word line WL.

A capping pattern 220 may be formed on the upper surface of the word line WL, the upper surface of the protective pattern 110, and the upper surface of the second insulating pattern 130. When forming the capping pattern 220, the upper surface of the first insulating pattern 120 and the upper surfaces of the first and second vertical portions V1 and V2 may be exposed to the outside.

Landing pads LP may be formed on the first and second vertical portions V1 and V2 of the semiconductor pattern SP, respectively. Forming the landing pads LP may include forming a recessed region by removing upper portions of the first and second vertical portions V1 and V2, forming landing pad layer that fills the recessed region and covers the capping pattern 220, and separating a portion of the landing pad layer into a plurality of landing pads.

A third interlayer insulating layer 240 may be formed to fill a space between the landing pads LP on the first and second insulating patterns 120 and 130. Data storage patterns DSP may be formed on each of the landing pads LP. The data storage patterns DSP may be electrically connected to the first and second vertical portions V1 and V2 of the semiconductor pattern SP through the landing pads LP, respectively.

An oxide semiconductor with a vertical channel structure is formed by depositing a channel material during forming a channel, and separating the channel through an etching process using an etch mask. However, there may be a problem that interfacial by-products occur due to depositing the etch mask on the channel material, and the etch process for the vertical structure is highly difficult. Accordingly, dispersion of channels may occur due to process difficulty, and electrical characteristics and reliability of the semiconductor device may be deteriorated.

According to various example embodiments, as described above with reference to FIGS. 9A to 15D and 16, after forming the mold pattern 122, the semiconductor layer SL may be deposited in the second trench region TR2. Depositing the semiconductor layer SL may be suppressed on the mold pattern 122 due to the hydrogen plasma surface treatment process (H2 treatment), and the semiconductor layer SL may be selectively deposited in a desired region. For example, there is no process for depositing an etch mask on the channel material, and thus the interfacial by-products do not occur. Alternatively or additionally, the etching process is not performed on the vertical structure, which has a high process difficulty, thereby improving the distribution of the channels. Alternatively or additionally, as the etching process is not performed on the vertical structure, the upper surface 104a of the second interlayer insulating layer 104 between the bit lines BL may not be recessed. Accordingly, the upper surface 104a of the second interlayer insulating layer 104 and the uppermost surface BLa of the bit line BL may be coplanar with each other.

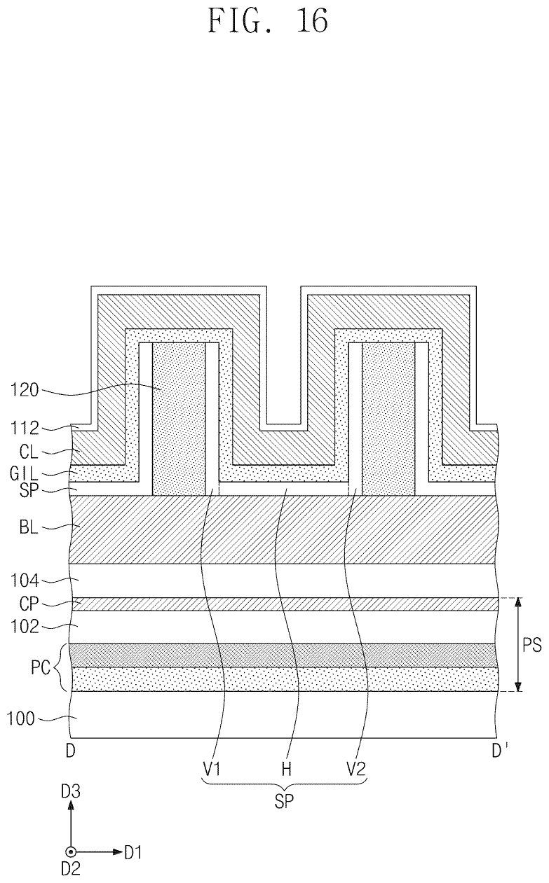

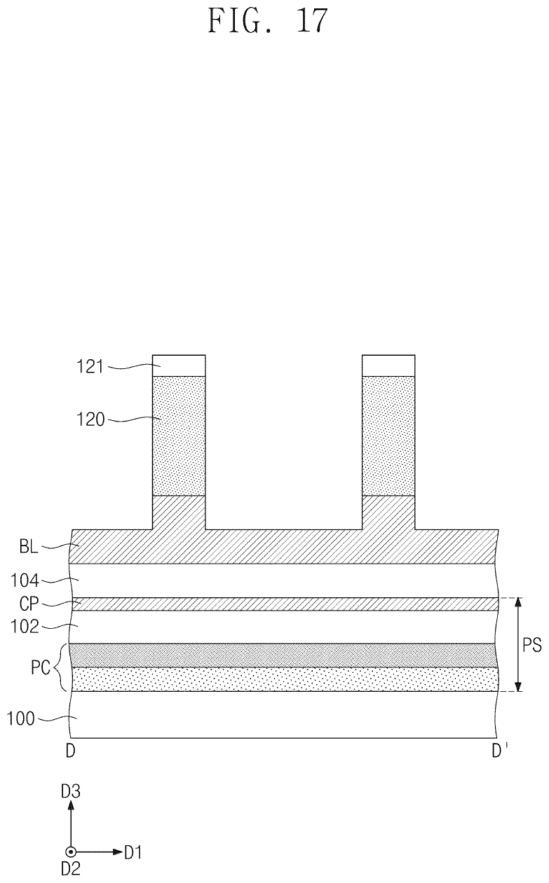

FIG. 17 is a cross-sectional view showing a process for manufacturing the semiconductor device of FIGS. 7C and 7D. To simplify the explanation, descriptions of content that overlaps with the above-described content are omitted.

Referring to FIG. 17, a first insulating pattern 120 and a sacrificial pattern 121 may be formed. Forming the first insulating pattern 120 and the sacrificial pattern 121 may include forming a mask pattern (not shown) on the sacrificial layer 121L, and sequentially etching the sacrificial layer 121L and the first insulating layer 120L using the mask pattern as an etch mask, and removing the mask pattern. In the etching process, a portion of an upper portion of the bit line BL may be recessed. Accordingly, an upper surface of the bit line BL may have a concave-convex structure.

In a subsequent process, through substantially the same process as described above with reference to FIGS. 11A to 15D, the semiconductor pattern SP may include a first vertical portion V1 and a second vertical portion V2 facing each other, and a horizontal portion H connecting the second vertical portions V1 and V2. When forming the semiconductor pattern SP, lower portions of the first and second vertical portions V1 and V2 and at least a portion of the horizontal portion H may be buried in the upper portion of the bit line BL. Accordingly, the semiconductor device shown in FIG. 7C may be manufactured through the above-described subsequent process.

Although not shown, when forming the semiconductor pattern SP, the horizontal portion H may be removed. Accordingly, as shown in FIG. 7D, the semiconductor pattern SP may include first and second vertical portions V1 and V2, and the first and second vertical portions V1 and V2 are spaced apart from each other. In a subsequent process, the semiconductor device shown in FIG. 7D may be manufactured through substantially the same process as described above with reference to FIGS. 11A to 15D.

According to various example embodiments, there may be no interfacial by-products in the channel material, thereby improving the electrical characteristics and/or the reliability of the semiconductor device.

Additionally or alternatively, according to various example embodiments, the etching process may not be performed on the vertical structure with the high processing difficulty to improve the distribution of the channels, thereby improving the electrical characteristics and/or reliability of the semiconductor device.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While various example embodiments are described above, a person skilled in the art may understand that many modifications and variations are made without departing from the spirit and scope of inventive concepts defined in the following claims. Accordingly, example embodiments of inventive concepts should be considered in all respects as illustrative and not restrictive, with the spirit and scope being indicated by the appended claims. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor device comprising:
peripheral circuit structures on a substrate;
an interlayer insulating layer on the peripheral circuit structure;
a bit line in the interlayer insulating layer and extending in a first direction;
a semiconductor pattern on the bit line, and including first vertical portion and second vertical portion facing each other in the first direction and a horizontal portion connecting the first and second vertical portions to each other;
first word line and second word line adjacent to the first and second vertical portions, respectively, on the horizontal portion; and
a gate insulating pattern interposed between the first vertical portion and the first word line, and between the second vertical portion and the second word line,
wherein an upper surface of the interlayer insulating layer and an upper surface of the bit line are coplanar with each other.

2. The semiconductor device of claim 1, wherein
the horizontal portion includes a first region and a second region, and
the second region is on first and second ends of the first region in a second direction, the second direction parallel to the upper surface of the substrate and intersecting the first direction,
the second region protrudes from the first region in a third direction perpendicular to the upper surface of the substrate, and
the second region extends in the first direction.

3. The semiconductor device of claim 2, wherein a thickness of the first region in the third direction is 1.5 nm to 10 nm.

4. The semiconductor device of claim 1, wherein
the horizontal portion has a first width in a second direction parallel to the upper surface of the substrate and intersecting the first direction,
the first and second vertical portions have a second width in the second direction, and
the first width and the second width are the same as each other.

5. The semiconductor device of claim 4, wherein
the horizontal portion includes a first region and a second region,
the second region is on first and second ends of the first region in the second direction, protrudes from the first region in a third direction perpendicular to the upper surface of the substrate, and extends in the first direction.

6. The semiconductor device of claim 1, wherein at least a portion of the horizontal portion is buried in an upper portion of the bit line.

7. The semiconductor device of claim 1, wherein a lower surface of the horizontal portion is a same height as the uppermost surface of the bit line.

8. The semiconductor device of claim 1, wherein the semiconductor pattern includes an oxide semiconductor.

9. The semiconductor device of claim 1, further comprising:
landing pads on the first and second vertical portions of the semiconductor pattern; and
data storage patterns disposed on the landing pads, respectively.

10. A semiconductor device comprising:
peripheral circuit structures on a substrate;
an interlayer insulating layer on the peripheral circuit structure;
a bit line extending in the interlayer insulating layer and in a first direction;
a semiconductor pattern on the bit line, and including first vertical portion and second vertical portion facing each other and spaced apart from each other in the first direction;
first word line and second word line respectively arranged on inner surfaces of the first and second vertical portions; and
a gate insulating pattern interposed between the first vertical portion and the first word line, and between the second vertical portion and the second word line,
wherein an upper surface of the interlayer insulating layer and an upper surface of the bit line are coplanar with each other.

11. The semiconductor device of claim 10, wherein lower portions of the first and second vertical portions are buried in an upper portion of the bit line.

12. The semiconductor device of claim 10, wherein lower surfaces of the first and second vertical portions are at a same height as the uppermost surface of the bit line.

13. The semiconductor device of claim 10, wherein the semiconductor pattern includes an oxide semiconductor.

14. A method of manufacturing a semiconductor device, the method comprising:
forming peripheral circuit structures on a substrate;
forming an interlayer insulating layer on the peripheral circuit structure;
forming a bit line in the interlayer insulating layer;
sequentially stacking a first insulating layer and a sacrificial layer on the interlayer insulating layer and the bit line;
patterning the first insulating layer and the sacrificial layer to form a first insulating pattern and a sacrificial pattern crossing the bit line;
forming a mold layer covering the first insulating pattern and the sacrificial pattern;
patterning the mold layer to form a mold pattern crossing the first insulating pattern and the sacrificial pattern; and
performing a surface treatment process on the mold pattern such that a surface of the mold pattern has hydrophobicity.

15. The method of claim 14, wherein the mold pattern includes carbon.

16. The method of claim 15, wherein the surface treatment process uses hydrogen plasma.

17. The method of claim 16, further comprising:
forming a semiconductor layer on an upper surface of the bit line, a side surface of the first insulating pattern, and a side surface and upper surface of the sacrificial pattern.

18. The method of claim 17, wherein the semiconductor layer is not formed on the mold pattern.

19. The method of claim 17, wherein the semiconductor layer includes a portion adjacent to the mold pattern and protruding in a direction perpendicular to the upper surface of the substrate.

20. The method of claim 17, further comprising:
patterning the semiconductor layer to form semiconductor patterns spaced apart from each other on the bit line,
wherein the patterning of the semiconductor layer includes removing the sacrificial pattern and a portion of the semiconductor layer formed on the side and upper surfaces of the sacrificial pattern.
